(19) United States
(12) Patent Application Publication
(10) Pub. No.: US 2022/0385022 A1
(43) Pub. Date: Dec. 1, 2022

(54) LINE NARROWING GAS LASER DEVICE, CONTROL METHOD THEREOF, AND ELECTRONIC DEVICE MANUFACTURING METHOD

(71) Applicant: Gigaphoton Inc., Tochigi (JP)

(72) Inventors: Takahito KUMAZAKI, Oyama-shi (JP); Osamu WAKABAYASHI, Oyama-shi (JP)

(73) Assignee: Gigaphoton Inc., Tochigi (JP)

(21) Appl. No.: 17/818,180

(22) Filed: Aug. 8, 2022

Related U.S. Application Data
(63) Continuation of application No. PCT/JP2020/012545, filed on Mar. 19, 2020.

(51) Int. Cl. H01S 3/036; H01S 3/1055; H01S 3/225

(52) U.S. Cl. CPC H01S 3/036; H01S 3/1055; H01S 3/225

(57) ABSTRACT

A control method of a line narrowing gas laser device includes receiving a command of either a single-wavelength mode command or a multi-wavelength mode command from an external apparatus, and controlling the line narrowing gas laser device to generate pulse laser light in accordance with the command.

### CROSS-REFERENCE TO RELATED APPLICATIONS

The present application claims the benefit of International Application No. PCT/JP2020/012545, filed on Mar. 19, 2020 the entire contents of which are hereby incorporated by reference.

### BACKGROUND

### 1. Technical Field

The present disclosure relates to a line narrowing gas laser device, a control method thereof, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material through which ultraviolet rays such as KrF laser light and ArF laser light are transmitted, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: U.S. Pat. No. 7,088,758
Patent Document 2: U.S. Pat. No. 7,154,928
Patent Document 3: International Publication No. WO2019/079010
Patent Document 4: Japanese Patent Application Publication No. 2006-269628

### SUMMARY

A control method of a line narrowing gas laser device according to an aspect of the present disclosure includes receiving a command of either a single-wavelength mode command or a multi-wavelength mode command from an external apparatus, and controlling the line narrowing gas laser device to generate pulse laser light in accordance with the command.

Aline narrowing gas laser device according to an aspect of the present disclosure includes a laser chamber, an optical resonator including a line narrowing device, and a processor. Here, the processor is configured to receive, from an external apparatus, a command being either a single-wavelength mode command or a multi-wavelength mode command and to control the line narrowing gas laser device to generate pulse laser light in accordance with the command.

An electronic device manufacturing method according to an aspect of the present disclosure includes generating pulse laser light using a line narrowing gas laser device, outputting the pulse laser light to an exposure apparatus, and exposing a photosensitive substrate to the pulse laser light in the exposure apparatus to manufacture an electronic device. Here, the line narrowing gas laser device includes a laser chamber, an optical resonator including a line narrowing device, and a processor. The processor is configured to receive, from an external apparatus, a command being either a single-wavelength mode command or a multi-wavelength mode command and to control the line narrowing gas laser device to generate the pulse laser light in accordance with the command.

### BRIEF DESCRIPTION OF THE DRAWINGS

Embodiments of the present disclosure will be described below merely as examples with reference to the accompanying drawings.

FIG. 1 schematically shows the configuration of an exposure system of a comparative example.

FIG. 2 schematically shows the configuration of the exposure system of the comparative example.

FIG. 3A schematically shows the configuration of a line narrowing device of the comparative example.

FIG. 3B schematically shows the configuration of the line narrowing device of the comparative example.

FIG. 4A schematically shows the configuration of the line narrowing device of a first embodiment.

FIG. 4B schematically shows the configuration of the line narrowing device of the first embodiment.

FIG. 4C schematically shows the configuration of the line narrowing device of the first embodiment.

FIG. 4D schematically shows the configuration of the line narrowing device of the first embodiment.

FIG. 5 is a flowchart showing the processing procedure of an exposure control processor in the first embodiment.

FIG. 6 is a flowchart showing the processing procedure of a single-wavelength mode in the first embodiment.

FIG. 7 is a flowchart showing the processing procedure of wavelength control in the single-wavelength mode.

FIG. 8 is a flowchart showing the processing procedure of energy control in the single-wavelength mode.

FIG. 9 is a flowchart showing the processing procedure of a two-wavelength mode in the first embodiment.

FIG. 10 is a flowchart showing the processing procedure of wavelength control in the two-wavelength mode.

FIG. 11 is a flowchart showing the processing procedure of energy control in the two-wavelength mode.

FIG. 12 is a flowchart showing the processing procedure of energy ratio control in the two-wavelength mode.

FIG. 13A schematically shows the configuration of the line narrowing device of the second embodiment.

FIG. 13B schematically shows the configuration of the line narrowing device of the second embodiment.

FIG. 13C schematically shows the configuration of the line narrowing device of the second embodiment.

FIG. 13D schematically shows the configuration of the line narrowing device of the second embodiment.

FIG. 14A is a graph showing changes of an oscillation wavelength in the second embodiment.

FIG. 14B is a graph showing changes of the oscillation wavelength in the second embodiment.

FIG. 14C is a graph showing changes of the oscillation wavelength in the second embodiment.

FIG. 15 is a flowchart showing the processing procedure of the single-wavelength mode in the second embodiment.

FIG. 16 is a flowchart showing the processing procedure of the two-wavelength mode in the second embodiment.

FIG. 17A is a flowchart showing the processing procedure of wavelength control in the two-wavelength mode.

FIG. 17B is a flowchart showing the processing procedure of wavelength control in the two-wavelength mode.

FIG. 18 is a flowchart showing the processing procedure of energy control in the two-wavelength mode.

### DESCRIPTION OF EMBODIMENTS

### Content

1. Comparative example

1.1 Exposure system
1.1.1 Configuration of exposure apparatus 100
1.1.2 Operation

1.2 Line narrowing gas laser device
1.2.1 Configuration
1.2.1.1 Master oscillator MO
1.2.1.2 Laser control processor 30
1.2.1.3 Gas adjustment device GA
1.2.2 Operation
1.2.2.1 Laser control processor 30
1.2.2.2 Master oscillator MO
1.2.2.3 Gas adjustment device GA

1.3 Line narrowing device
1.3.1 Configuration
1.3.1.1 First and second prisms 41, 42
1.3.1.2 Grating system 50
1.3.2 Operation
1.3.3 Problem of comparative example
   2. Line narrowing gas laser device performing switching between single-wavelength mode and multiple-wavelength mode

2.1 Configuration

2.2 Operation of line narrowing gas laser device

2.3 Operation of exposure control processor 110
2.3.1 Single-wavelength mode
2.3.2 Two-wavelength mode
2.3.3 Exposure control

2.4 Operation of single-wavelength mode by laser control processor 30
2.4.1 Wavelength control in single-wavelength mode
2.4.2 Energy control in single-wavelength mode

2.5 Operation of two-wavelength mode by laser control processor 30
2.5.1 Wavelength control in two-wavelength mode
2.5.2 Energy control in two-wavelength mode

2.6 Other configuration example

2.7 Effect

3. Line narrowing gas laser device performing wavelength switching on pulse-by-pulse basis

3.1 Configuration

3.2 Operation of line narrowing gas laser device

3.3 Operation of single-wavelength mode by laser control processor 30

3.4 Operation of two-wavelength mode by laser control processor 30
3.4.1 Wavelength control in two-wavelength mode
3.4.1.1 Process for determining posture of second prism 42
3.4.1.2 Process for determining amplitude of first prism 41
3.4.2 Energy control in two-wavelength mode

3.5 Other configuration example

3.6 Effect

### 4. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. Comparative Example

### 1.1 Exposure System

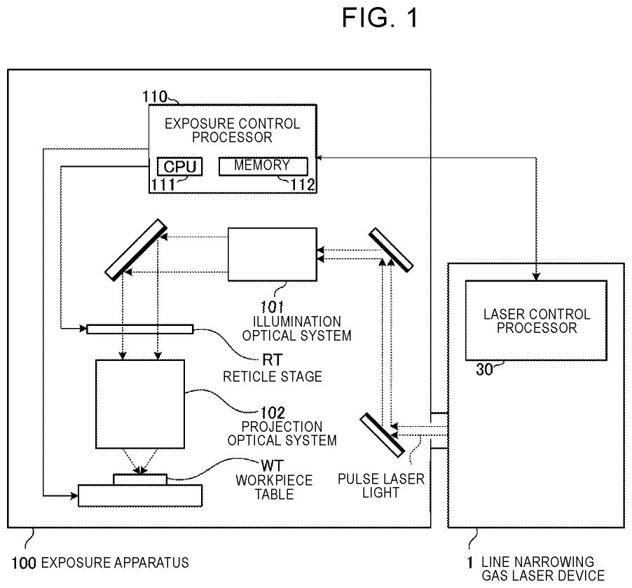

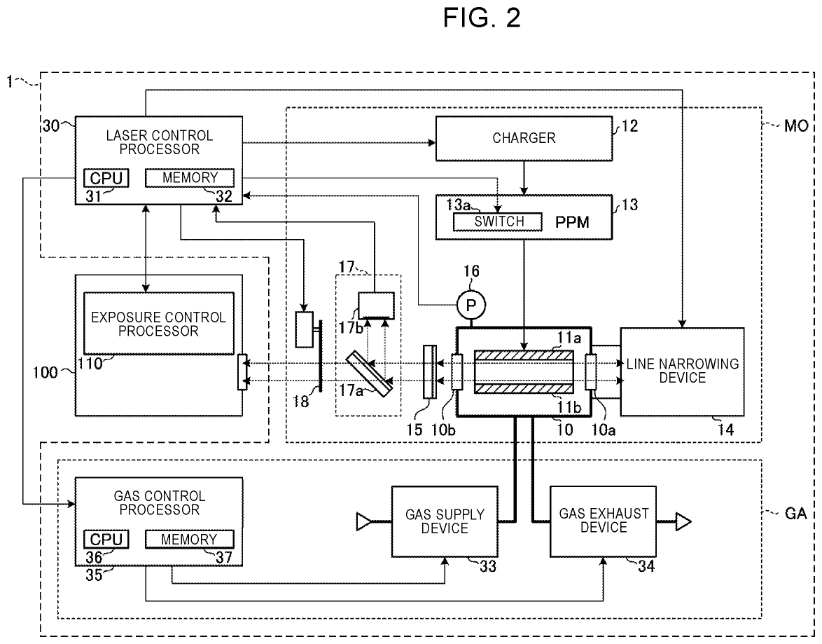

FIGS. 1 and 2 schematically show the configuration of an exposure system of a comparative example. The comparative example of the present disclosure is an example recognized by the applicant as known only by the applicant, and is not a publicly known example admitted by the applicant.

The exposure system includes a line narrowing gas laser device 1 and an exposure apparatus 100. In FIG. 1, the line narrowing gas laser device 1 is shown in a simplified manner. In FIG. 2, the exposure apparatus 100 is shown in a simplified manner.

The line narrowing gas laser device 1 includes a laser control processor 30. The line narrowing gas laser device 1 is configured to output pulse laser light toward the exposure apparatus 100.

### 1.1.1 Configuration of Exposure Apparatus 100

As shown in FIG. 1, the exposure apparatus 100 includes an illumination optical system 101, a projection optical system 102, and an exposure control processor 110. The exposure apparatus 100 corresponds to an external apparatus in the present disclosure.

The illumination optical system 101 illuminates a reticle pattern of a reticle (not shown) arranged on a reticle stage RT with the pulse laser light incident from the line narrowing gas laser device 1.

The projection optical system 102 causes the pulse laser light transmitted through the reticle to be imaged as being reduced and projected on a workpiece (not shown) arranged on a workpiece table WT. The workpiece is a photosensitive substrate such as a semiconductor wafer coated with a resist film.

The exposure control processor 110 is a processing device including a memory 112 in which a control program is stored, and a central processing unit (CPU) 111 which executes the control program. The exposure control processor 110 is specifically configured or programmed to perform various processes included in the present disclosure. The exposure control processor 110 controls the exposure apparatus 100, and transmits and receives various data and various signals to and from the laser control processor 30.

### 1.1.2 Operation

The exposure control processor 110 transmits data of a target value of the wavelength, data of a target value of the pulse energy, and a trigger signal to the laser control processor 30. The laser control processor 30 controls the line narrowing gas laser device 1 in accordance with the data and signal.

The exposure control processor 110 translates the reticle stage RT and the workpiece table WT in opposite directions in synchronization with each other. Thus, the workpiece is exposed to the pulse laser light reflecting the reticle pattern.

Through such an exposure process, the reticle pattern is transferred onto the semiconductor wafer. Thereafter, an electronic device can be manufactured through a plurality of processes.

### 1.2 Line Narrowing Gas Laser Device

### 1.2.1 Configuration

As shown in FIG. 2, in addition to the laser control processor 30, the line narrowing gas laser device 1 includes a master oscillator MO and a gas adjustment device GA.

1.2.1.1 Master Oscillator MO

The master oscillator MO includes a laser chamber 10, a charger 12, a pulse power module (PPM) 13, a line narrowing device 14, an output coupling mirror 15, a photodetector 17, and a shutter 18. The line narrowing device 14 and the output coupling mirror 15 configure an optical resonator.

The laser chamber 10 is arranged on the optical path of the optical resonator.

The laser chamber 10 is provided with two windows 10a, 10b. The laser chamber 10 includes a pair of electrodes 11a, 11b therein, and further accommodates laser gas as a laser medium. The laser medium is, for example, F₂, ArF, KrF, XeCl, or XeF.

A pressure sensor 16 is attached to the laser chamber 10.

The charger 12 holds electric energy to be supplied to the pulse power module 13. The pulse power module 13 includes a switch 13a.

The line narrowing device 14 includes wavelength selection elements such as first and second prisms 41, 42 and gratings 51, 52, which will be described later.

The output coupling mirror 15 is configured by a partial reflection mirror.

The photodetector 17 includes a beam splitter 17a and a sensor unit 17b. The beam splitter 17a is arranged on the optical path of the pulse laser light output from the output coupling mirror 15. The beam splitter 17a is configured to cause a part of the pulse laser light to be transmitted therethrough at high transmittance and to reflect another part of the pulse laser light to be incident on the sensor unit 17b. The sensor unit 17b includes a spectral sensor and is configured to be capable of outputting the measurement data of the wavelength. Further, the sensor unit 17b includes an energy sensor and is configured to be capable of outputting the measurement data of the pulse energy.

The shutter 18 is arranged on the optical path of the pulse laser light transmitted through the beam splitter 17a. When the shutter 18 is closed, the pulse laser light transmitted through the beam splitter 17a is blocked so as not to enter the exposure apparatus 100. When the shutter 18 is open, the pulse laser light transmitted through the beam splitter 17a enters the exposure apparatus 100 without being blocked.

### 1.2.1.2 Laser Control Processor 30

The laser control processor 30 is a processing device including a memory 32 in which a control program is stored and a CPU 31 for executing the control program. The laser control processor 30 is specifically configured or programmed to perform various processes included in the present disclosure.

### 1.2.1.3 Gas Adjustment Device GA

The gas adjustment device GA includes a gas supply device 33, a gas exhaust device 34, and a gas control processor 35.

The gas supply device 33 includes a valve (not shown) provided at a first pipe between the laser chamber 10 and a gas cylinder (not shown).

The gas exhaust device 34 includes a valve (not shown) provided at the second pipe connected to the laser chamber 10, a pump (not shown), and a detoxification device (not shown).

The gas control processor 35 is a processing device including a memory 37 in which a control program is stored and a CPU 36 for executing the control program. The gas control processor 35 is specifically configured or programmed to perform various processes included in the present disclosure.

### 1.2.2 Operation

### 1.2.2.1 Laser Control Processor 30

The laser control processor 30 acquires data of the target value of the wavelength from the exposure control processor 110. The laser control processor 30 transmits an initial setting signal to the line narrowing device 14 based on the target value of the wavelength. After outputting of the pulse laser light is started, the laser control processor 30 receives the measurement data of the wavelength from the photodetector 17 and transmits a feedback control signal to the line narrowing device 14 based on the target value of the wavelength and the measurement data of the wavelength.

The laser control processor 30 acquires data of the target value of the pulse energy from the exposure control processor 110. The laser control processor 30 transmits an initial setting signal of the charge voltage to the charger 12 based on the target value of the pulse energy. After outputting of the pulse laser light is started, the laser control processor 30 receives the measurement data of the pulse energy from the photodetector 17 and transmits a feedback control signal of the charge voltage to the charger 12 based on the target value of the pulse energy and the measurement data of the pulse energy.

The laser control processor 30 receives a trigger signal from the exposure control processor 110. The laser control processor 30 transmits an oscillation trigger signal based on the trigger signal to the switch 13a of the pulse power module 13.

The laser control processor 30 transmits a gas control signal to the gas control processor 35. Further, the laser control processor 30 receives the measurement data of the gas pressure P from the pressure sensor 16 and transmits the measurement data of the gas pressure P to the gas control processor 35.

### 1.2.2.2 Master Oscillator MO

The switch 13a is turned on when the oscillation trigger signal is received from the laser control processor 30. When the switch 13a is turned on, the pulse power module 13 generates a high pulse voltage from the electric energy held in the charger 12. The pulse power module 13 applies the high voltage between the electrodes 11a, 11b.

When the high voltage is applied between the electrodes 11a, 11b, discharge occurs between the electrodes 11a, 11b. The laser gas in the laser chamber 10 is excited by the energy of the discharge and shifts to a high energy level. When the excited laser gas then shifts to a low energy level, light having a wavelength corresponding to the difference between the energy levels is emitted.

The light generated in the laser chamber 10 is output to the outside of the laser chamber 10 through the windows 10a, 10b. The light output from the window 10a enters the line narrowing device 14 as a light beam. The light in the vicinity of the desired wavelength among the light having entered the line narrowing device 14 is fed back by the line narrowing device 14 and returned to the laser chamber 10.

The output coupling mirror 15 causes a part of the light output from the window 10b to be transmitted therethrough and output therefrom, and another part thereof to be reflected back into the laser chamber 10.

In this way, the light output from the laser chamber 10 reciprocates between the line narrowing device 14 and the output coupling mirror 15. The light is amplified every time when passing through a discharge space between the pair of discharge electrodes 11a, 11b. Thus, the light having undergone laser oscillation and line narrowing is output as pulse laser light from the output coupling mirror 15.

The pulse laser light output from the line narrowing gas laser device 1 enters the exposure apparatus 100.

### 1.2.2.3 Gas Adjustment Device GA

The gas control processor 35 controls the gas supply device 33 and the gas exhaust device 34 so that the gas pressure P inside the laser chamber 10 becomes a desired value based on the gas control signal and the measurement data of the gas pressure P received from the laser control processor 30.

For example, when increasing the gas pressure P inside the laser chamber 10, the gas control processor 35 performs control to open the valve included in the gas supply device 33 so that the laser gas is supplied into the laser chamber 10. Also, for example, when decreasing the gas pressure P inside the laser chamber 10, the gas control processor 35 performs control to open the valve included in the gas exhaust device 34 so that a part of the laser gas inside the laser chamber 10 is exhausted.

### 1.3 Line Narrowing Device

### 1.3.1 Configuration

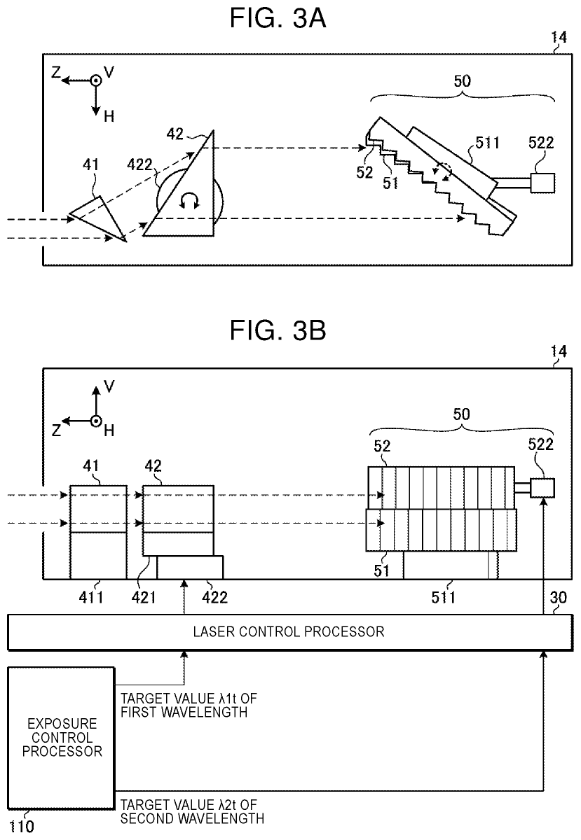

FIGS. 3A and 3B schematically show the configuration of the line narrowing device 14 of the comparative example. In each figure, the V axis, the H axis, and the Z axis perpendicular to each other are shown. FIG. 3A shows the line narrowing device 14 viewed in the −V direction, and FIG. 3B shows the line narrowing device 14 viewed in the −H direction. The −V direction and the +V direction coincide with a direction in which the electrodes 11a, 11b (see FIG. 2) face each other. The −Z direction coincides with the travel direction of the light beam output from the window 10a. The +Z direction coincides with the travel direction of the pulse laser light output from the window 10b and the output coupling mirror 15.

The line narrowing device 14 includes first and second prisms 41, 42 and a grating system 50.

### 1.3.1.1 First and Second Prisms 41, 42

The first prism 41 is arranged on the optical path of the light beam output from the window 10a. The first prism 41 is supported by a holder 411.

The second prism 42 is arranged on the optical path of the light beam having passed through the first prism 41. The second prism 42 is supported by a holder 421.

The first and second prisms 41, 42 are made of a material such as calcium fluoride and synthetic quartz having high transmittance for the selected wavelength by the line narrowing device 14.

The first and second prisms 41, 42 are arranged such that the surfaces of the first and second prisms 41, 42 which the light beam is incident on and output from are parallel to the V axis. The second prism 42 is rotatable about an axis parallel to the V axis by a rotation stage 422.

### 1.3.1.2 Grating System 50

The grating system 50 includes gratings 51, 52. The gratings 51, 52 are arranged at positions different from each other in the V-axis direction on the optical path of the light beam having passed through the second prism 42. The directions of the grooves of the respective gratings 51, 52 coincide with the V-axis direction. The positions of the gratings 51, 52 are set such that the light beam having passed through the second prism 42 is incident on across the gratings 51, 52.

The gratings 51, 52 are supported by a holder 511. However, while the grating 51 is supported to maintain constant posture, the grating 52 is rotatable about an axis parallel to the V axis by a rotation mechanism 522.

### 1.3.2 Operation

The travel direction of the light beam output from the window 10a is changed in a plane parallel to the HZ plane which is a plane perpendicular to the V axis by each of the first and second prisms 41, 42, and the beam width thereof is expanded in the plane parallel to the HZ plane. For example, the travel direction of the light beam having passed through both the first and second prisms 41, 42 toward the gratings 51, 52 substantially coincides to the −Z direction.

The light incident on the gratings 51, 52 from the second prism 42 is reflected by the plurality of grooves of each of the gratings 51, 52 and is diffracted in a direction corresponding to the wavelength of the light. As a result, the light reflected by the plurality of grooves of each of the gratings 51, 52 is dispersed in the plane parallel to the HZ plane. The grating 51 is arranged in the Littrow arrangement, which causes the incident angle of the light beam incident on the grating 51 from the second prism 42 to coincide with the diffraction angle of the diffracted light having a desired first wavelength λ1. The grating 52 is arranged in the Littrow arrangement, which causes the incident angle of the light beam incident on the grating 52 from the second prism 42 to coincide with the diffraction angle of the diffracted light having a desired second wavelength λ2. When the incident angles of the light beams incident on the gratings 51, 52 from the second prism 42 are different from each other, a wavelength difference occurs between the first wavelength λ1 of the diffracted light returned from the grating 51 to the second prism 42 and the second wavelength λ2 of the diffracted light returned from the grating 52 to the second prism 42.

In FIGS. 3A and 3B, broken-line arrows indicating light beams show only the direction from the first prism 41 toward the gratings 51, 52, but the light beams having wavelengths selected by the line narrowing device 14 travel from the gratings 51, 52 toward the first prism 41 along paths opposite to the broken line arrows.

The second prism 42 and the first prism 41 reduce the beam width of the light returned from the gratings 51, 52 in the plane parallel to the HZ plane, and return the light into the laser chamber 10 through the window 10a.

The rotation stage 422 and the rotation mechanism 522 are controlled by the laser control processor 30.

When the rotation stage 422 slightly rotates the second prism 42, the travel direction of the light beam output from the second prism 42 toward the gratings 51, 52 slightly changes in the plane parallel to the HZ plane. Thus, the incident angles of the light beams incident on the gratings 51, 52 from the second prism 42 slightly change. Therefore, both the first wavelength λ1 and the second wavelength λ2 are changed.

When the rotation mechanism 522 slightly rotates the grating 52, the incident angle of the light beam incident on the grating 51 from the second prism 42 does not change, but the incident angle of the light beam incident on the grating 52 from the second prism 42 slightly changes. Thus, the wavelength difference between the first wavelength λ1 and the second wavelength λ2 changes.

The exposure control processor 110 transmits a target value λ1t of the first wavelength λ1 and a target value λ2t of the second wavelength λ2 to the laser control processor 30.

The laser control processor 30 controls the rotation stage 422 based on the target value λ1t of the first wavelength λ1. Thus, the rotation stage 422 changes the posture of the second prism 42 and adjusts the incident angle (first incident angle) of the light beam on the grating 51 and the incident angle (second incident angle) thereof on the grating 52.

The laser control processor 30 controls the rotation mechanism 522 based on the target value λ2t of the second wavelength λ2. Thus, the rotation mechanism 522 changes the posture of the grating 52 and adjusts the incident angle of the light beam on the grating 52.

With the above configuration and operation, the light beams having the first wavelength λ1 and the second wavelength λ2 output from the window 10a of the laser chamber 10 are selected and returned to the laser chamber 10. Thus, the line narrowing gas laser device 1 can perform two-wavelength oscillation. By controlling the rotation stage 422 and the rotation mechanism 522, it is also possible to separately set the first wavelength λ1 and the second wavelength λ2.

The focal length in the exposure apparatus 100 (see FIG. 1) depends on the wavelength of the pulse laser light. The pulse laser light output from the line narrowing gas laser device 1 through two-wavelength oscillation can be imaged, on the workpiece table WT of the exposure apparatus 100, at two different positions in the direction of the optical path axis of the pulse laser light, and the depth of focus can be substantially increased. For example, even when a resist film having a large thickness is to be exposed, it is possible to suppress variations in imaging performance in the thickness direction of the resist film.

1.3.3 Problem of comparative example

According to the comparative example, two-wavelength oscillation can be performed, but it is not easy to switch from two-wavelength oscillation to single-wavelength oscillation in the same line narrowing gas laser device 1. When it is desired to perform exposure with two wavelengths and exposure with one wavelength in the same exposure apparatus 100, there is a problem that replacing the laser device impairs efficiency.

In some embodiments described below, the line narrowing gas laser device 1 is controlled by switching between a single-wavelength mode and a multiple-wavelength mode in accordance with a command from an external apparatus.

### 2. Line Narrowing Gas Laser Device Performing Switching Between Single-Wavelength Mode and Multiple-Wavelength Mode

### 2.1 Configuration

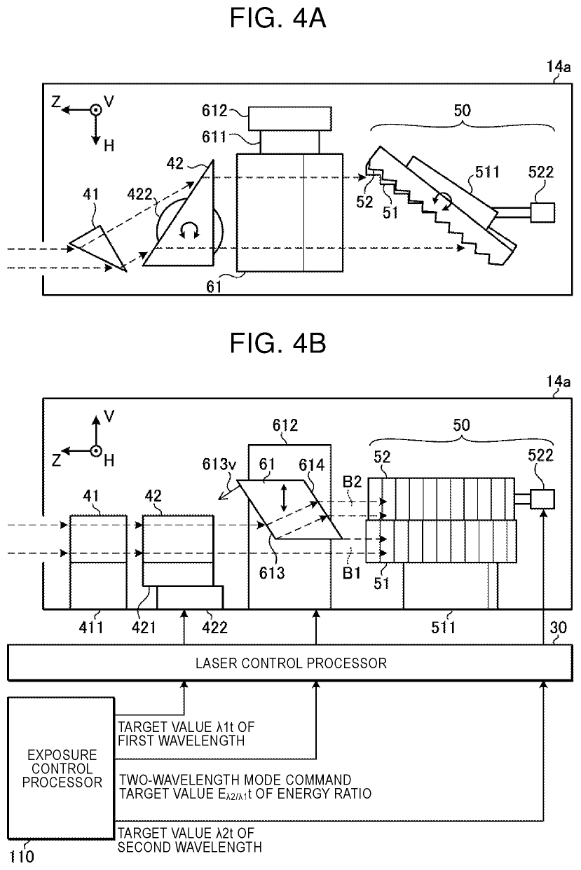

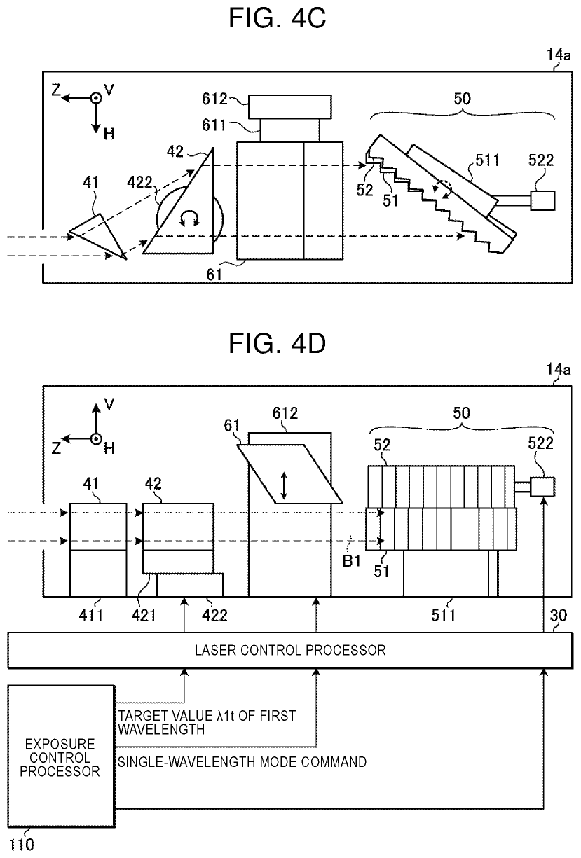

FIGS. 4A to 4D schematically show the configuration of a line narrowing device 14a of a first embodiment. FIGS. 4A and 4C show the line narrowing device 14a viewed in the −V direction, and FIGS. 4B and 4D show the line narrowing device 14a viewed in the −H direction. FIGS. 4A and 4B show the line narrowing device 14a in the two-wavelength mode, and FIGS. 4C and 4D show the line narrowing device 14a in the single-wavelength mode.

The line narrowing device 14a includes a plane-parallel substrate 61 as a beam adjustment optical system.

The plane-parallel substrate 61 is arranged so as to overlap with a part of the cross section of the optical path of the light beam having passed through the second prism 42. The plane-parallel substrate 61 is arranged on the optical path of the light beam between the second prism 42 and the grating 52. The plane-parallel substrate 61 is supported by a holder 611. The plane-parallel substrate 61 is made of a material such as calcium fluoride and synthetic quartz. The plane-parallel substrate 61 is configured to be movable in the −V direction and the +V direction by a linear stage 612. The linear stage 612 corresponds to the adjustment mechanism in the present disclosure.

The plane-parallel substrate 61 includes an incidence surface 613 on which a part of the light beam having passed through the second prism 42 is incident, and an exit surface 614 from which the light incident on the plane-parallel substrate 61 through the incidence surface 613 is output toward the grating 52 from the inside of the plane-parallel substrate 61 (see FIG. 4B). The incidence surface 613 and the exit surface 614 are both parallel to the H axis and parallel to each other. The incidence surface 613 and the exit surface 614 are inclined with respect to the incident direction of the light beam so as to refract the light beam. Specifically, a normal line vector 613v of the incidence surface 613 is parallel to the VZ plane, and further, the normal line vector 613v has direction components in the −V direction and the +Z direction.

### 2.2 Operation of Line Narrowing Gas Laser Device

A first portion B1 of the light beam having passed through the second prism 42 passes through the outside of the plane-parallel substrate 61 and is incident on the grating 51. A second portion B2 of the light beam passes through the inside of the plane-parallel substrate 61 and is incident on the grating 52. That is, the line narrowing device 14a including the plane-parallel substrate 61 causes the first portion B1 of the light beam to be incident on the grating 51 and the second portion B2 of the light beam to be incident on the grating 52. At this time, the plane-parallel substrate 61 shifts the optical path axis of the second portion B2 of the light beam in the +V direction with respect to the optical path axis of the first portion B1. The optical path axis refers to the center axis of the optical path. Thus, the plane-parallel substrate 61 adjusts the optical path of a part of the light beam by causing the part of the light beam to be transmitted therethrough.

Further, when the linear stage 612 changes the position of the plane-parallel substrate 61 in the V-axis direction, the ratio of the first portion B1 and the second portion B2 is changed.

When the second portion B2 of the light beam incident on the plane-parallel substrate 61 is increased by moving the plane-parallel substrate 61 in the −V direction, the amount of light incident on the grating 52 increases.

Therefore, the energy of the wavelength component of the second wavelength λ2 included in the pulse laser light increases. When the second portion B2 of the light beam incident on the plane-parallel substrate 61 is decreased by moving the plane-parallel substrate 61 in the +V direction, the amount of light incident on the grating 52 decreases. Therefore, the energy of the wavelength component of the second wavelength λ2 included in the pulse laser light decreases.

The movement direction of the plane-parallel substrate 61 by the linear stage 612 may not be the V-axis direction. The linear stage 612 may move the plane-parallel substrate 61 in a direction intersecting the HZ plane which is a plane perpendicular to the V axis.

As shown in FIGS. 4C and 4D, the linear stage 612 may minimize the ratio of the second portion B2 to the first portion B1 by retracting the plane-parallel substrate 61 from the optical path of the light beam. The minimum value is, for example, 0. That is, the entire light beam may be incident on the grating 51 as the first portion B1. Thus, switching from the two-wavelength mode to the single-wavelength mode can be performed.

In the two-wavelength mode shown in FIGS. 4A and 4B, the exposure control processor 110 transmits a two-wavelength mode command, the target value λ1t of the first wavelength λ1, the target value λ2t of the second wavelength λ2, and a target value E_{λ2/λ1}t of the energy ratio to the laser control processor 30.

The laser control processor 30 controls the linear stage 612 based on the two-wavelength mode command and the target value E_{λ2/λ1}t of the energy ratio. Thus, the linear stage 612 adjusts the position of the plane-parallel substrate 61 and adjusts the energy ratio of the wavelength component of the first wavelength λ1 selected by the grating 51 and the wavelength component of the second wavelength λ2 selected by the grating 52.

The laser control processor 30 controls the rotation stage 422 based on the target value λ1t of the first wavelength λ1. Thus, the rotation stage 422 changes the posture of the second prism 42 and adjusts the first incident angle of the first portion B1 of the light beam on the grating 51.

The laser control processor 30 controls the rotation mechanism 522 based on the target value λ2t of the second wavelength λ2. Thus, the rotation mechanism 522 changes the posture of the grating 52 and adjusts the second incident angle of the second portion B2 of the light beam on the grating 52.

The surface of the grating 51 on which the light beam is incident corresponds to the first region of the grating system 50 in the present disclosure. The surface of the grating 52 on which the light beam is incident corresponds to the second region of the grating system 50 in the present disclosure.

In the single-wavelength mode shown in FIGS. 4C and 4D, the exposure control processor 110 transmits a single-wavelength mode command and the target value λ1t of the first wavelength λ1 to the laser control processor 30.

The laser control processor 30 controls the linear stage 612 based on the single-wavelength mode command. The linear stage 612 causes the entire light beam to be incident on the grating 51 as the first portion B1 by retracting the plane-parallel substrate 61 from the optical path of the light beam.

The laser control processor 30 controls the rotation stage 422 based on the target value λ1t of the first wavelength λ1. Thus, the rotation stage 422 changes the posture of the second prism 42 and adjusts the first incident angle of the light beam on the grating 51.

### 2.3 Operation of Exposure Control Processor 110

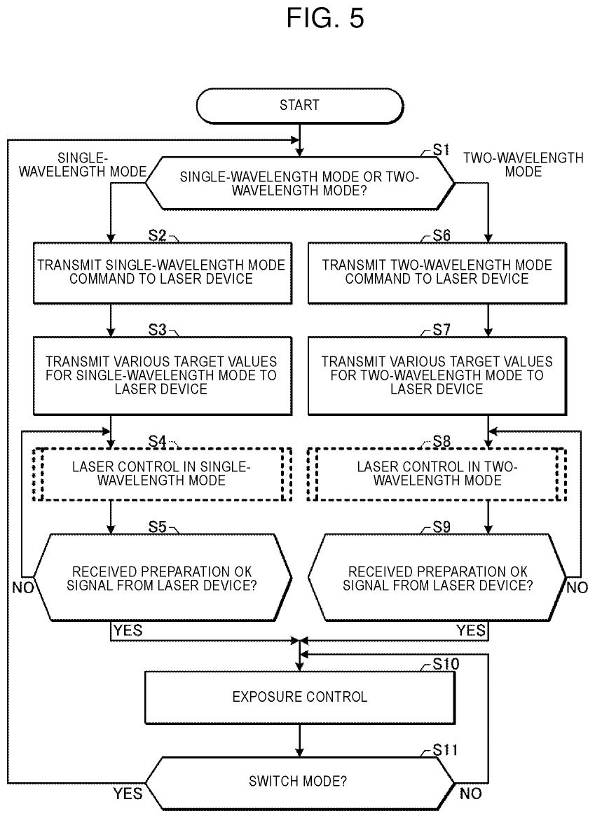

FIG. 5 is a flowchart showing a processing procedure of the exposure control processor 110 in the first embodiment. The exposure control processor 110 causes the line narrowing gas laser device 1, by the following processing, to perform laser oscillation in the single-wavelength mode or the two-wavelength mode and performs exposure with the pulse laser light.

In S1, the exposure control processor 110 determines whether to cause the line narrowing gas laser device 1 to perform laser oscillation in the single-wavelength mode or in the two-wavelength mode.

When causing the line narrowing gas laser device 1 to perform laser oscillation in the single-wavelength mode, the exposure control processor 110 advances processing to S2.

When causing the line narrowing gas laser device 1 to perform laser oscillation in the two-wavelength mode, the exposure control processor 110 advances processing to S6.

### 2.3.1 Single-Wavelength Mode

In S2, the exposure control processor 110 transmits the single-wavelength mode command to the line narrowing gas laser device 1. The laser control processor 30 of the line narrowing gas laser device 1 receives the single-wavelength mode command.

In S3 after S2 or simultaneously with S2, the exposure control processor 110 transmits various target values for the single-wavelength mode to the line narrowing gas laser device 1. The laser control processor 30 receives the various target values. The various target values include the target value λ1t of the first wavelength λ1.

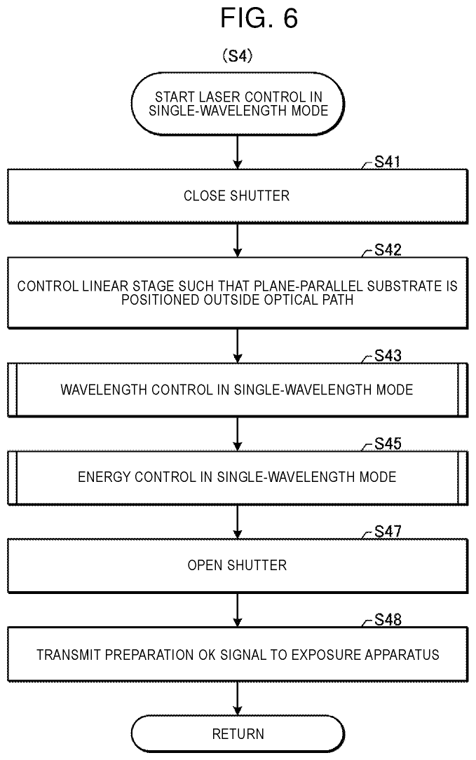

In S5 after S3, the exposure control processor 110 waits until a preparation OK signal is received from the laser control processor 30. That is, the exposure control processor 110 repeats the determination of whether or not the preparation OK signal is received until the preparation OK signal is received. In S4 between S3 and S5, the laser control processor 30 performs laser control in the single-wavelength mode and outputs the preparation OK signal when the laser control is completed. Details of the process of S4 will be described later with reference to FIG. 6.

Upon receiving the preparation OK signal in S5, the exposure control processor 110 advances processing to S10.

### 2.3.2 Two-Wavelength Mode

In S6, the exposure control processor 110 transmits the two-wavelength mode command to the line narrowing gas laser device 1. The laser control processor 30 receives the two-wavelength mode command.

In S7 after S6 or simultaneously with S6, the exposure control processor 110 transmits various target values for the two-wavelength mode to the line narrowing gas laser device 1. The laser control processor 30 receives the various target values. The various target values include the target value λ′1t of the first wavelength λ1, the target value λ′2t of the second wavelength λ2, and the target value E_{λ2/λ1}t of the energy ratio E_{λ2/λ1}.

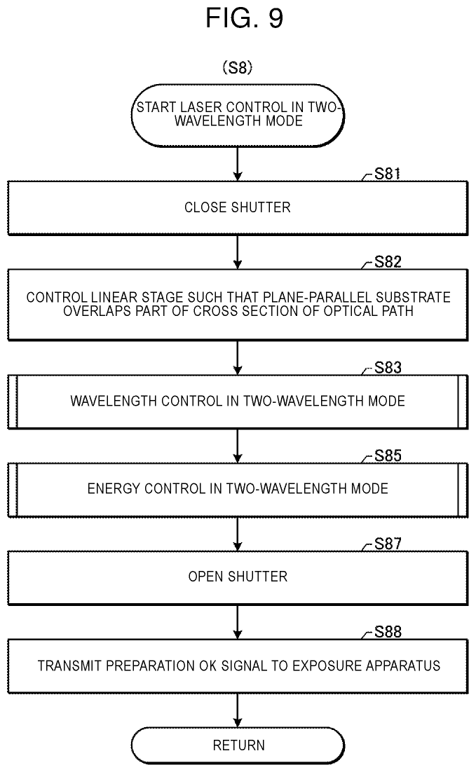

In S9 after S7, the exposure control processor 110 waits until the preparation OK signal is received from the laser control processor 30. That is, the exposure control processor 110 repeats the determination of whether or not the preparation OK signal is received until the preparation OK signal is received. In S8 between S7 and S9, the laser control processor 30 performs laser control in the two-wavelength mode and outputs the preparation OK signal when the laser control is completed. Details of the process of S8 will be described later with reference to FIG. 9.

Upon receiving the preparation OK signal in S9, the exposure control processor 110 advances processing to S10.

### 2.3.3 Exposure Control

In S10, the exposure control processor 110 performs exposure control. The exposure control includes control of the reticle stage RT and the workpiece table WT, transmission of the trigger signal to the line narrowing gas laser device 1, and the like.

In S11 after S10, the exposure control processor 110 determines whether or not to switch the mode between the single-wavelength mode and the two-wavelength mode. When the mode is not to be switched (NO in S11), the exposure control processor 110 returns processing to S10 and continues the exposure control. When the mode is to be switched (YES in S11), the exposure control processor 110 returns processing to 51 and switches the mode.

### 2.4 Operation of Single-Wavelength Mode by Laser Control Processor 30

FIG. 6 is a flowchart showing a processing procedure of the single-wavelength mode in the first embodiment. When the laser control processor 30 receives the single-wavelength mode command and various target values from the exposure control processor 110, the laser control processor 30 performs laser control in the single-wavelength mode by the following processing.

In S41, the laser control processor 30 closes the shutter 18. This makes it possible to prevent the pulse laser light from entering the exposure apparatus 100.

Next, in S42, the laser control processor 30 controls the linear stage 612 such that the plane-parallel substrate 61 is positioned outside the optical path of the light beam, that is, such that the energy ratio E_{λ2/λ1} of the wavelength component of the second wavelength λ2 is minimized.

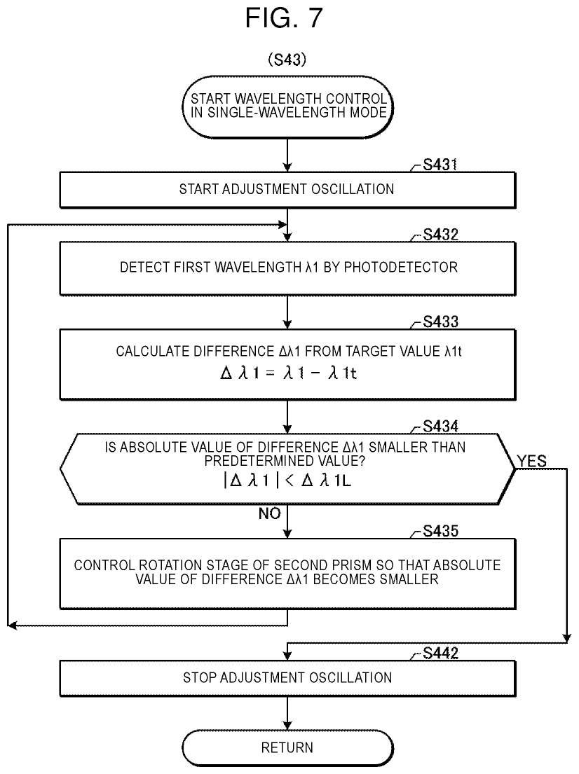

Next, in S43, the laser control processor 30 performs wavelength control in the single-wavelength mode. The wavelength control in the single-wavelength mode will be described later with reference to FIG. 7.

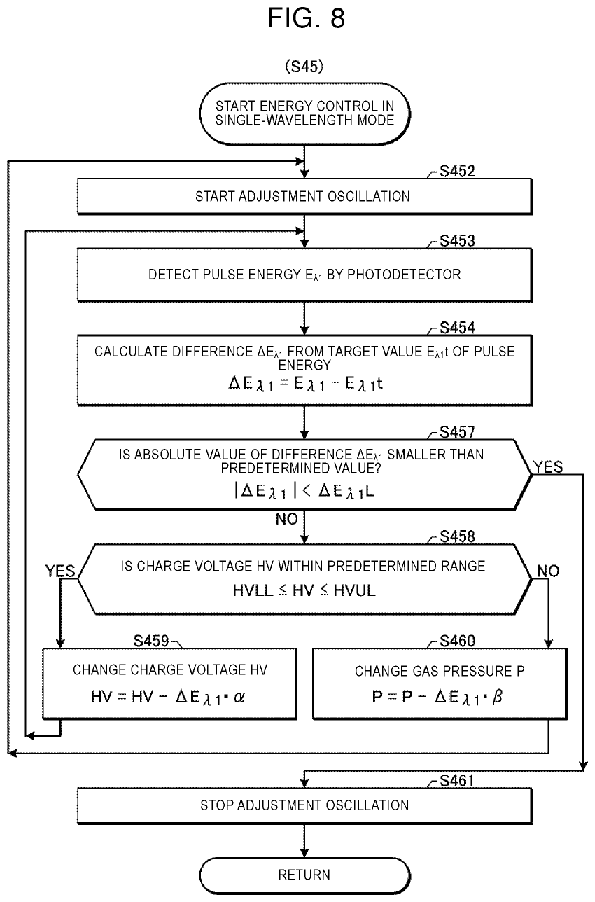

Next, in S45, the laser control processor 30 performs energy control in the single-wavelength mode. The energy control in the single-wavelength mode will be described later with reference to FIG. 8.

Next, in S47, the laser control processor 30 opens the shutter 18. This makes it possible to cause the pulse laser light to enter the exposure apparatus 100.

Next, in S48, the laser control processor 30 transmits the preparation OK signal to the exposure control processor 110 of the exposure apparatus 100. After S48, the laser control processor 30 ends processing of the present flowchart.

### 2.4.1 Wavelength Control in Single-Wavelength Mode

FIG. 7 is a flowchart showing a processing procedure of the wavelength control in the single-wavelength mode. The processing shown in FIG. 7 corresponds to the subroutine of S43 in FIG. 6.

In S431, the laser control processor 30 starts adjustment oscillation to set the wavelength.

Next, in S432, the laser control processor 30 detects the first wavelength λ1 by the photodetector 17.

Next, in S433, the laser control processor 30 calculates the difference Δλ1 between the detected first wavelength λ1 and the target value λ1t of the first wavelength λ1 by the following equation.

Δλ1=λ1−λ1t

Next, in S434, the laser control processor 30 determines whether or not the absolute value |Δλ1| of the difference Δλ1 is smaller than a predetermined value Δλ1L. When the absolute value |Δλ1| of the difference Δλ1 is equal to or larger than the predetermined value Δλ1L (NO in S434), the laser control processor 30 advances processing to S435. When the absolute value |Δλ1| of the difference Δλ1 is smaller than the predetermined value Δλ1L (YES in S434), the laser control processor 30 advances processing to S442.

In S435, the laser control processor 30 controls the rotation stage 422 of the second prism 42 so that the absolute value |Δλ1| of the difference Δλ1 becomes smaller. After S435, the laser control processor 30 returns processing to S432.

In S442, the laser control processor 30 stops the adjustment oscillation. After S442, the laser control processor 30 ends the processing of the present flowchart and returns to the processing shown in FIG. 6.

### 2.4.2 Energy Control in Single-Wavelength Mode

FIG. 8 is a flowchart showing a processing procedure of the energy control in the single-wavelength mode. The processing shown in FIG. 8 corresponds to the subroutine of S45 in FIG. 6.

In S452, the laser control processor 30 starts the adjustment oscillation to set the pulse energy.

Next, in S453, the laser control processor 30 detects the pulse energy E_{λ1} by the photodetector 17.

Next, in S454, the laser control processor 30 calculates the difference ΔE_{λ1} between the detected pulse energy E_{λ1} and the target value E_{λ1}t of the pulse energy E_{λ1} by the following equation.

ΔE_{λ1}=E_{λ1}−E_{λ1}t

Next, in S457, the laser control processor 30 determines whether or not the absolute value |ΔE_{λ1}| of the difference ΔE_{λ1} is smaller than a predetermined value ΔE_{λ1}L. When the absolute value |ΔE_{λ1}| of the difference ΔE_{λ1} is equal to or larger than the predetermined value ΔE_{λ1}L (NO in S457), the laser control processor 30 advances processing to S458. When the absolute value |ΔE_{λ1}| of the difference ΔE_{λ1} is smaller than the predetermined value ΔE_{λ1}L (YES in S457), the laser control processor 30 advances processing to S461.

In S458, the laser control processor 30 determines whether or not a charge voltage HV of the charger 12 (see FIG. 2) is within a predetermined range. For example, it is determined whether or not the charge voltage HV is equal to or higher than a lower limit value HVLL and equal to or lower than an upper limit value HVUL. When the charge voltage HV is within the predetermined range (YES in S458), the laser control processor 30 advances processing to S459. When the charge voltage HV is not within the predetermined range (NO in S458), the laser control processor 30 advances processing to S460.

In S459, the laser control processor 30 changes the charge voltage HV by the following equation.

HV=HV−ΔE_{λ1}·α

Here, α is a positive constant. For example, when the pulse energy E_{λ1} is larger than the target value E_{λ1}t, the pulse energy E_{λ1} can be decreased by decreasing the charge voltage HV in accordance with the difference ΔE_{λ1}. After S459, the laser control processor 30 returns processing to S453.

In S460, the laser control processor 30 changes the gas pressure P in the laser chamber 10 by the following equation.

P=P−ΔE_{λ1}·β

Here, β is a positive constant. Changing of the gas pressure P is performed by the gas adjustment device GA (see FIG. 2). For example, when the pulse energy E_{λ1} is larger than the target value E_{λ1}t, the pulse energy E_{λ1} can be decreased by decreasing the gas pressure P in accordance with the difference ΔE_{λ1}. After S460, the laser control processor 30 returns processing to S452.

In S461, the laser control processor 30 stops the adjustment oscillation. After S461, the laser control processor 30 ends the processing of the present flowchart and returns to the processing shown in FIG. 6.

### 2.5 Operation of Two-Wavelength Mode by Laser Control Processor 30

FIG. 9 is a flowchart showing a processing procedure of the two-wavelength mode in the first embodiment. When the laser control processor 30 receives the two-wavelength mode command and various target values from the exposure control processor 110, the laser control processor 30 performs laser control in the two-wavelength mode by the following processing.

In S81, the laser control processor 30 closes the shutter 18. This makes it possible to prevent the pulse laser light from entering the exposure apparatus 100.

Next, in S82, the laser control processor 30 controls the linear stage 612 such that the plane-parallel substrate 61 overlaps with a part of the cross section of the optical path of the light beam, that is, such that the energy ratio E_{λ2/λ1} of the wavelength component of the second wavelength λ2 becomes larger than the minimum value.

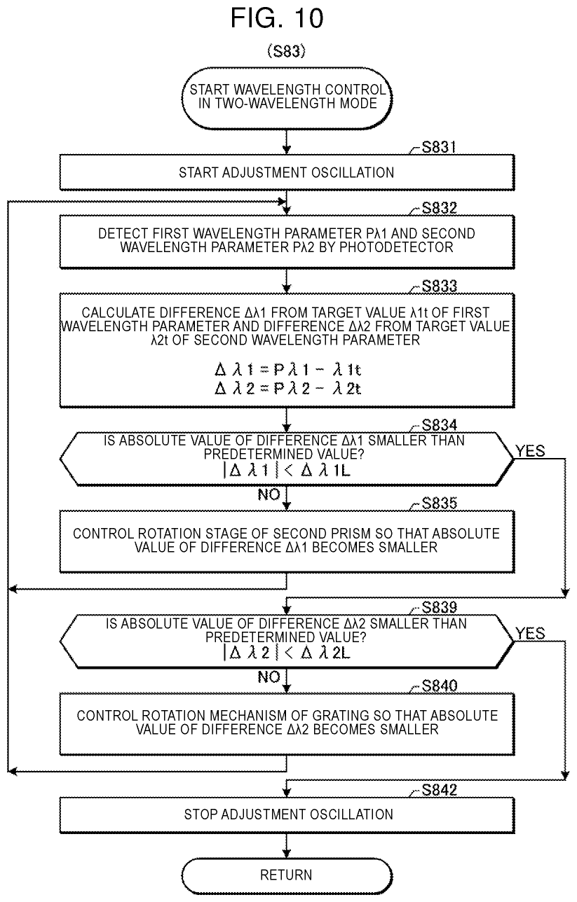

Next, in S83, the laser control processor 30 performs the wavelength control in the two-wavelength mode. The wavelength control in the two-wavelength mode will be described later with reference to FIG. 10.

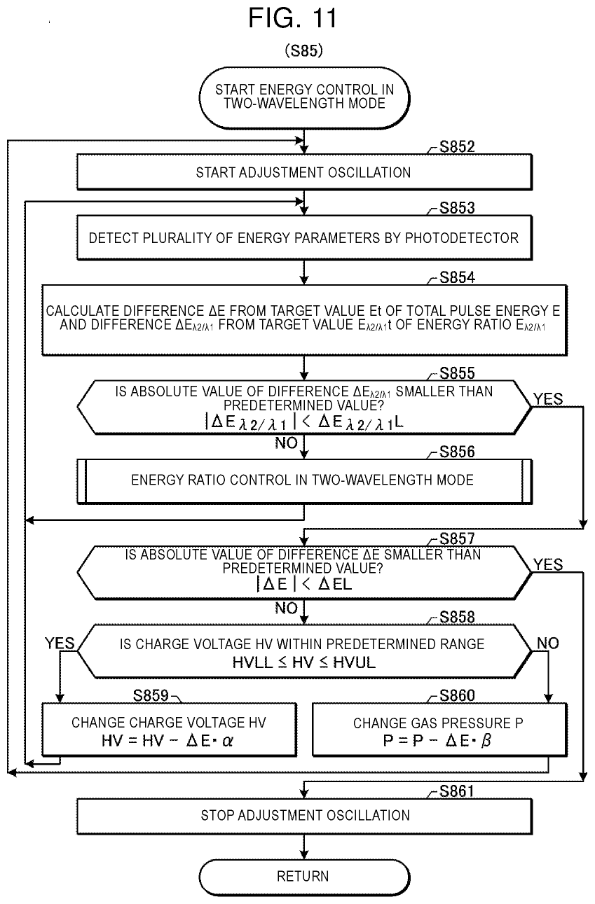

Next, in S85, the laser control processor 30 performs the energy control in the two-wavelength mode. The energy control in the two-wavelength mode will be described later with reference to FIG. 11

Next, in S87, the laser control processor 30 opens the shutter 18. This makes it possible to cause the pulse laser light to enter the exposure apparatus 100.

Next, in S88, the laser control processor 30 transmits the preparation OK signal to the exposure control processor 110 of the exposure apparatus 100. After S88, the laser control processor 30 ends processing of the present flowchart.

### 2.5.1 Wavelength Control in Two-Wavelength Mode

FIG. 10 is a flowchart showing a processing procedure of the wavelength control in the two-wavelength mode. The processing shown in FIG. 10 corresponds to the subroutine of S83 in FIG. 9.

In S831, the laser control processor 30 starts adjustment oscillation to set the wavelength.

Next, in S832, the laser control processor 30 detects a plurality of wavelength parameters by the photodetector 17. The plurality of wavelength parameters include a first wavelength parameter Pλ1 and a second wavelength parameter Pλ2.

The first wavelength parameter Pλ1 includes, for example, the first wavelength λ1 selected by the grating 51 on which the first portion B1 of the light beam is incident.

The second wavelength parameter Pλ2 includes, for example, one of the following (1) and (2).

(1) The second wavelength λ2 selected by the grating 52 on which the second portion B2 of the light beam is incident
(2) The wavelength difference λ2−λ1 between the first wavelength λ1 and the second wavelength λ2

Next, in S833, the laser control processor 30 reads the target value λ1t of the first wavelength parameter Pλ1 and the target value λ2t of the second wavelength parameter Pλ2 from the memory 32 (see FIG. 2). Thereafter, the laser control processor 30 calculates differences Δλ1, Δλ2 respectively between the detected first wavelength parameter Pλ1 and the target value λ1t thereof and between the detected second parameter Pλ2 and the target value λ2t thereof according to the following equations.

Δλ1=Pλ1−λ1t

Δλ2=Pλ2−λ2t

Next, in S834, the laser control processor 30 determines whether or not the absolute value |Δλ1| of the difference Δλ1 is smaller than a predetermined value Δλ1L. When the absolute value |Δλ1| of the difference Δλ1 is equal to or larger than the predetermined value Δλ1L (NO in S834), the laser control processor 30 advances processing to S835. When the absolute value |Δλ1| of the difference Δλ1 is smaller than the predetermined value Δλ1L (YES in S834), the laser control processor 30 advances processing to S839.

In S835, the laser control processor 30 controls the rotation stage 422 of the second prism 42 so that the absolute value |Δλ1| of the difference Δλ1 becomes smaller. After S835, the laser control processor 30 returns processing to S832. Thus, the laser control processor 30 controls the rotation stage 422 of the second prism 42 based on the first wavelength parameter Pλ1 and the target value λ1t thereof.

In S839, the laser control processor 30 determines whether or not the absolute value |Δλ1 of the difference Δλ2 is smaller than a predetermined value Δλ2L. When the absolute value |Δλ1 of the difference Δλ2 is equal to or larger than the predetermined value Δλ2L (NO in S839), the laser control processor 30 advances processing to S840. When the absolute value |Δλ1 of the difference Δλ2 is smaller than the predetermined value Δλ2L (YES in S839), the laser control processor 30 advances processing to S842.

In S840, the laser control processor 30 controls the rotation mechanism 522 of the grating 52 so that the absolute value |Δλ2| of the difference Δλ2 becomes smaller. After S840, the laser control processor 30 returns processing to S832. Thus, the laser control processor 30 controls the rotation mechanism 522 of the second grating 52 based on the second wavelength parameter Pλ2 and the target value λ2t thereof.

In S842, the laser control processor 30 stops the adjustment oscillation. After S842, the laser control processor 30 ends the processing of the present flowchart and returns to the processing shown in FIG. 9.

### 2.5.2 Energy Control in Two-Wavelength Mode

FIG. 11 is a flowchart showing a processing procedure of the energy control in the two-wavelength mode. The processing shown in FIG. 11 corresponds to the subroutine of S85 in FIG. 9.

In S852, the laser control processor 30 starts the adjustment oscillation to set the pulse energy.

Next, in S853, the laser control processor 30 detects a plurality of energy parameters including an energy ratio parameter by the photodetector 17. The plurality of energy parameters include, for example, one of the following (1) to (3).

(1) Combination of E_{λ1} and E_{λ2}
(1-1) E_{λ1} is the energy of the wavelength component of the first wavelength λ1.
(1-2) E_{λ2} is the energy of the wavelength component of the second wavelength λ2.
(2) Combination of E_{λ1R}, E_{λ2R}, and E
(2-1) E_{λ1R} is a value obtained by dividing the energy E_{λ1} of the wavelength component of the first wavelengths λ1 by the sum of the energy E_{λ1} of the wavelength component of the first wavelength λ1 and the energy E_{λ2} of the wavelength component of the second wavelength λ2, and is calculated by the following equation.

E_{λ1R}=E_{λ1}/(E_{λ1}+E_{λ2})

(2-2) E_{λ2R} is a value obtained by dividing the energy E_{λ2} of the wavelength component of the second wavelength λ2 by the sum of the energy E_{λ1} of the wavelength component of the first wavelength λ1 and the energy E_{λ2} of the wavelength component of the second wavelength λ2, and is calculated by the following equation.

E_{λ2R}=E_{λ2}/(E_{λ1}+E_{λ2})

(2-3) E is the total pulse energy of the pulse laser light. E corresponds to the sum of the energy E_{λ1} of the wavelength component of the first wavelength λ1 and the energy E_{λ2} of the wavelength component of the second wavelength λ2.

### (3) Combination of E_{λ2/λ1} and E

(3-1) E_{λ2/λ1} is the energy ratio obtained by dividing the energy E_{λ2} of the wavelength component of the second wavelength λ2 by the energy E_{λ1} of the wavelength component of the first wavelength λ1, and can be calculated by the following equation.

E_{λ2/λ1}=E_{λ2}/E_{λ1}

(3-2) E is the total pulse energy of the pulse laser light.

Using the energy parameters of (1) or (2) above, the energy ratio E_{λ2/λ1} and the total pulse energy E described in (3) above can be calculated.

(1) Calculation Based on Combination of E_{λ1} and E_{λ2}

The energy ratio E_{λ2/λ1} can be calculated by the following equation.

E_{λ2/λ1}=E_{λ2}/E_{λ1}

The total pulse energy E can be calculated by the following equation.

E=E_{λ1}+E_{λ2}

(2) Calculation Based on Combination of E_{λ1R}, E_{λ2R}, and E

The energy ratio E_{λ2/λ1} can be calculated by the following equation.

E_{λ2/λ1}=E_{λ2R}/E_{λ1R}

Therefore, when the plurality of energy parameters listed in any of (1) to (3) above are detected in S853, it is possible to perform the processes of S854 and later.

Next, in S854, the laser control processor 30 reads the target value Et of the total pulse energy E and the target value E_{λ2/λ1}t of the energy ratio E_{λ2/λ1} from the memory 32 (see FIG. 2). The energy ratio E_{λ2/λ1} is one of the energy ratio parameters in the present disclosure. Thereafter, the laser control processor 30 calculates the difference ΔE between the detected total pulse energy E and the target value Et of the total pulse energy E by the following equation.

ΔE=E−Et

Further, the laser control processor 30 calculates the difference ΔE_{λ2/λ1} between the detected energy ratio E_{λ2/λ1} and the target value E_{λ2/λ1}t of the energy ratio E_{λ2/λ1} by the following equation.

ΔE_{λ2/λ1}=E_{λ2/λ1}−E_{λ2/λ1}t

Next, in S855, the laser control processor 30 determines whether or not the absolute value |ΔE_{λ2/λ1}| of the difference ΔE_{λ2/λ1} is smaller than a predetermined value ΔE_{λ2/λ1}L. When the absolute value |ΔE_{λ2/λ1}| of the difference ΔE_{λ2/λ1} is equal to or larger than the predetermined value ΔE_{λ2/λ1}L (NO in S855), the laser control processor 30 advances processing to S856. When the absolute value |ΔE_{λ2/λ1}| of the difference ΔE_{λ2/λ1} is smaller than the predetermined value ΔE_{λ2/λ1}L (YES in S855), the laser control processor 30 advances processing to S857.

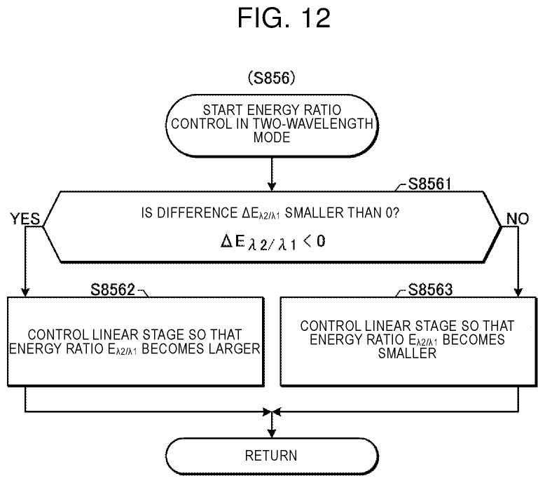

Next, in S856, the laser control processor 30 performs the energy control in the two-wavelength mode. Details of S856 will be described later with reference to FIG. 12. Thus, the laser control processor 30 controls the linear stage 612 based on the energy ratio E_{λ2/λ1} and the target value E_{λ2/λ1}t thereof. After S856, the laser control processor 30 returns processing to S853.

In S857, the laser control processor 30 determines whether or not the absolute value |ΔE| of the difference ΔE is smaller than a predetermined value ΔEL. When the absolute value |ΔE| of the difference ΔE is equal to or larger than the predetermined value ΔEL (NO in S857), the laser control processor 30 advances processing to S858. When the absolute value |ΔE| of the difference ΔE is smaller than the predetermined value ΔEL (YES in S857), the laser control processor 30 advances processing to S861.

In S858, the laser control processor 30 determines whether or not the charge voltage HV of the charger 12 (see FIG. 2) is within a predetermined range. For example, it is determined whether or not the charge voltage HV is equal to or higher than the lower limit value HVLL and equal to or lower than the upper limit value HVUL. When the charge voltage HV is within the predetermined range (YES in S858), the laser control processor 30 advances processing to S859. When the charge voltage HV is not within the predetermined range (NO in S858), the laser control processor 30 advances processing to S860.

In S859, the laser control processor 30 changes the charge voltage HV by the following equation.

HV=HV−ΔE−α

Here, α is a positive constant. For example, when the total pulse energy E is larger than the target value Et, the total pulse energy E can be decreased by decreasing the charge voltage HV in accordance with the difference ΔE. After S859, the laser control processor 30 returns processing to S853.

In S860, the laser control processor 30 changes the gas pressure P in the laser chamber 10 by the following equation.

P=P−ΔE·β

Here, β is a positive constant. The change of the gas pressure P is performed by the gas adjustment device GA (see FIG. 2). For example, when the total pulse energy E is larger than the target value Et, the total pulse energy E can be decreased by decreasing the gas pressure P in accordance with the difference ΔE.

Thus, the laser control processor 30 controls the charge voltage of the charger 12 or the gas pressure P in the laser chamber 10 based on the total pulse energy E and the target value Et thereof.

After S860, the laser control processor 30 returns processing to S852.

In S861, the laser control processor 30 stops the adjustment oscillation. After S861, the laser control processor 30 ends the processing of the present flowchart and returns to the processing shown in FIG. 9.

FIG. 12 is a flowchart showing a processing procedure of the energy ratio control in the two-wavelength mode. The processing shown in FIG. 12 corresponds to the subroutine of S856 in FIG. 11.

In 58561, the laser control processor 30 determines whether or not the difference ΔE_{λ2/λ1} between the energy ratio E_{λ2/λ1} and the target value E_{λ2/λ1}t thereof is smaller than 0. When the difference ΔE_{λ2/λ1} is smaller than 0 (YES in S8561), the laser control processor 30 advances processing to S8562. When the difference ΔE_{λ2/λ1} is equal to or larger than 0 (NO in S8561), the laser control processor 30 advances processing to S8563.

In S8562, the laser control processor 30 controls the linear stage 612 (see FIG. 4B) such that the energy ratio E_{λ2/λ1} is increased. That is, by moving the linear stage 612 in the −V direction, since the second portion B2 of the light beam is increased and the first portion B1 is decreased, the energy ratio E_{λ2/λ1} is increased.

In S8563, the laser control processor 30 controls the linear stage 612 such that the energy ratio E_{λ2/λ1} becomes smaller. That is, by moving the linear stage 612 in the +V direction, since the second portion B2 of the light beam is decreased and the first portion B1 is increased, the energy ratio E_{λ2/λ1} is decreased.

After 58562 or after 58563, the laser control processor 30 ends the processing of the present flowchart and returns to the processing shown in FIG. 11.

### 2.6 Other Configuration Example

In the first embodiment, description has been provided on a case in which the exposure control processor 110 included in the exposure apparatus 100 outputs the single-wavelength mode command, the two-wavelength mode command, data of other target values, and the like, but the present disclosure is not limited thereto. For example, a controller of an external apparatus (not shown) that controls a plurality of exposure apparatuses 100 may output these commands and data.

In the first embodiment, the line narrowing gas laser device 1 that includes the two gratings 51, 52 and is capable of performing switching between the single-wavelength mode and the two-wavelength mode has been described, but the present disclosure is not limited thereto. For example, the line narrowing gas laser device 1 may include three or more gratings and be capable of performing switching to laser oscillation at three or more wavelengths.

In the first embodiment, the line narrowing device 14a including the plane-parallel substrate 61 as the beam adjustment optical system has been described, but the present disclosure is not limited thereto. For example, the beam adjustment optical system may be configured to shift the position of the light beam by a combination of a plurality of prisms (not shown) and change the shift amount by moving any of the plurality of prisms.

In the first embodiment, description has been provided on a case in which the optical path axis is shifted by moving the plane-parallel substrate 61 by the linear stage 612 to perform switching between the single-wavelength mode and the two-wavelength mode, but the present disclosure is not limited thereto. A rotation stage (not shown) may rotate the plane-parallel substrate 61 about an axis parallel to the H axis to shift the optical path axis, thereby performing switching between the single-wavelength mode and the two-wavelength mode.

### 2.7 Effect

In the first embodiment, the laser control processor 30 receives a command of either the single-wavelength mode command or the multi-wavelength mode command from the exposure apparatus 100 which is an external apparatus. The laser control processor 30 controls the line narrowing gas laser device 1 so that the line narrowing gas laser device 1 generates the pulse laser light in accordance with the command. Thus, when the single-wavelength mode command is received, laser oscillation can be performed in the single-wavelength mode, and when the two-wavelength mode command is received, laser oscillation can be performed in the two-wavelength mode. It is not necessary to exchange the laser device between the single-wavelength mode and the two-wavelength mode, and the exposure process can be efficiently performed.

In the first embodiment, the line narrowing gas laser device 1 includes the line narrowing device 14a. The line narrowing device 14a includes the grating system 50, the plane-parallel substrate 61 which is the beam adjustment optical system, and the linear stage 612 which is the adjustment mechanism. The beam adjustment optical system is arranged on the optical path of the light beam, and adjusts the optical path of at least a part of the light beam so as to cause the first portion B1 of the light beam to be incident on the grating 51 and the second portion B2 of the light beams to be incident on the grating 52. The linear stage 612 adjusts the energy ratio E_{λ2/λ1} of the wavelength component of the second wavelength λ2 selected by the grating 52 with respect to the wavelength component of the first wavelength λ1 selected by the grating 51 by adjusting either the position or the posture of at least one optical element included in the beam adjustment optical system. In this configuration, when the single-wavelength mode command is received from the exposure apparatus 100 which is an external apparatus, the linear stage 612 is controlled so that the energy ratio E_{λ2/λ1} of the wavelength component of the second wavelength λ2 becomes the minimum value, and when the multiple-wavelength mode command is received from the external apparatus, the linear stage 612 is controlled so that the energy ratio E_{λ2/λ1} of the wavelength component of the second wavelength λ2 becomes larger than the minimum value. Thus, the linear stage 612 can perform switching between the single-wavelength mode and the two-wavelength mode by adjusting the position or posture of the optical element.

In the first embodiment, when the single-wavelength mode command is received from the external apparatus, the linear stage 612 adjusts the beam adjustment optical system so that the entire light beam is incident on the grating 51 as the first portion B1. Thus, switching to the single-wavelength mode can be performed with a simple configuration.

In the first embodiment, the line narrowing device 14a includes the rotation stage 422 which adjusts the incident angle of the first portion B1 on the grating 51, and the rotation mechanism 522 which adjusts the incident angle of the second portion B2 on the grating 52. The rotation stage 422 corresponds to the first actuator in the present disclosure, and the rotation mechanism 522 corresponds to the second actuator in the present disclosure. When receiving the multi-wavelength mode command from the external apparatus, the laser control processor 30 reads the target value λ1t of the first wavelength parameter Pλ1 for the first wavelength λ1 and the target value λ2t of the second wavelength parameter Pλ2 for the second wavelength λ2. The laser control processor 30 performs the adjustment oscillation to control the rotation stage 422 and the rotation mechanism 522 based on the respective target values λ1t, λ2t of the first and second wavelength parameters Pλ1, Pλ2. Thus, it is possible to bring the two wavelength components included in the pulse laser light close to the target values of the respective wavelength parameters.

In the first embodiment, the first wavelength parameter Pλ1 may include the first wavelength λ1, and the second wavelength parameter Pλ2 may include the second wavelength λ2. Thus, it is possible to specify the first and second wavelength parameters Pλ1, Pλ2.

In the first embodiment, the first wavelength parameter Pλ1 may include the first wavelength λ1, and the second wavelength parameter Pλ2 may include a wavelength difference λ2−λ1 between the first wavelength λ1 and the second wavelength λ2. Thus, it is possible to specify the first and second wavelength parameters Pλ1, Pλ2. It may be convenient to use the wavelength difference λ2−λ1 as the second wavelength parameter Pλ2 to control the rotation mechanism 522 which adjusts the relative posture of the grating 52 with respect to the grating 51.

In the first embodiment, when receiving the multi-wavelength mode command from the external apparatus, the laser control processor 30 reads the target value E_{λ2/λ1}t of the energy ratio as the target value of the energy ratio parameter between the wavelength component of the first wavelength λ1 and the wavelength component of the second wavelength λ2. After controlling the rotation stage 422 and the rotation mechanism 522 based on the target values of the wavelength parameters, the laser control processor 30 controls the linear stage 612 based on the target value E_{λ2/λ1}t of the energy ratio. Thus, it is possible to bring the energy ratio of the two wavelength components included in the pulse laser light close to the target value E_{λ2/λ1}t of the energy ratio.

In the first embodiment, the energy ratio parameter may include a combination of the energy E_{λ1} of the wavelength component of the first wavelength λ1 and the energy E_{λ2} of the wavelength component of the second wavelength λ2. Thus, it is possible to specify the energy ratio parameter.

In the first embodiment, the energy ratio parameter may include a value E_{λ2}/E_{λ1} obtained by dividing the energy E_{λ2} of the wavelength component of the second wavelength λ2 by the energy E_{λ1} of the wavelength component of the first wavelength λ1. Thus, it is possible to specify the energy ratio parameter.

In the first embodiment, the energy ratio parameter may include a value E_{λ1}/(E_{λ1}+E_{λ2}) obtained by dividing the energy E_{λ1} of the wavelength component of the first wavelength λ1 by the total value E_{λ1}+E_{λ2} obtained by adding the energy E_{λ1} of the wavelength component of the first wavelength λ1 and the energy E_{λ2} of the wavelength component of the wavelength component of the second wavelength λ2. Further, the energy ratio parameter may include a value E_{λ2}/(E_{λ1}+E_{λ2}) obtained by dividing the energy E_{λ2} of the wavelength component of the second wavelength λ2 by the above-mentioned total value E_{λ1}+E_{λ2}. Thus, it is possible to specify the energy ratio parameter.

In the first embodiment, when receiving the multi-wavelength mode command from the external apparatus, the laser control processor 30 reads the target value of the total pulse energy such as the total pulse energy of the wavelength component of the first wavelength λ1 and the wavelength component of the second wavelength λ2. After controlling the linear stage 612 based on the target value E_{λ2/λ1}t of the energy ratio, the laser control processor 30 controls the charge voltage HV of the charger 12 and the gas pressure P in the laser chamber 10 based on the target value Et of the total pulse energy. Thus, even when the total pulse energy E is changed by adjusting the energy ratio, the total pulse energy E can be brought close to the target value Et.

### 3. Line Narrowing Gas Laser Device Performing Wavelength Switching on Pulse-by-Pulse Basis

### 3.1 Configuration

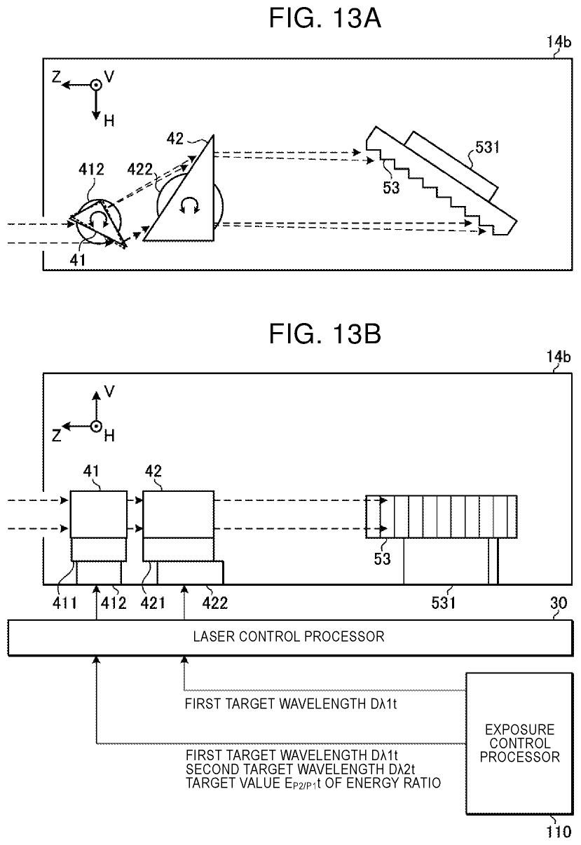

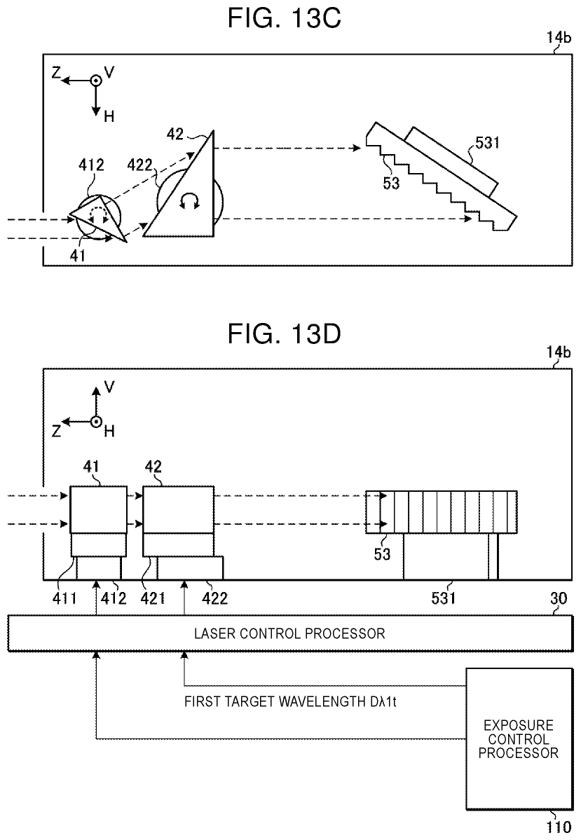

FIGS. 13A to 13D schematically show the configuration of a line narrowing device 14b of a second embodiment. FIGS. 13A and 13C show the line narrowing device 14b viewed in the −V direction, and FIGS. 13B and 13D show the line narrowing device 14b viewed in the −H direction. FIGS. 13A and 13B show the line narrowing device 14b in the two-wavelength mode, and FIGS. 13C and 13D show the line narrowing device 14b in the single-wavelength mode.

The line narrowing device 14b includes a grating 53 in place of the grating system 50. The grating 53 is arranged on the optical path of the light beam having passed through the second prism 42, and is supported by a holder 531 so as to maintain constant posture. The direction of the grooves of the grating 53 coincides with the V-axis direction.

The first prism 41 included in the line narrowing device 14b is rotatable about an axis parallel to the V axis by the rotation stage 412. Examples of the rotation stage 412 include a highly responsive rotation stage which rotates by a piezoelectric element.

The line narrowing device 14b may not include the beam adjustment optical system described in the first embodiment.

In other respects, the configuration of the second embodiment is similar to that of the first embodiment.

### 3.2 Operation of Line Narrowing Gas Laser Device

The light beam output from the window 10a passes through the first and second prisms 41, 42 and is incident on the grating 53. The wavelength of the light returned from the grating 53 via the second and first prisms 42, 41 to the laser chamber 10 is adjusted by the posture of these prisms.

In the two-wavelength mode shown in FIGS. 13A and 13B, the laser control processor 30 controls the rotation stage 422 for the second prism 42 based on a first target wavelength Dλ1t received from the exposure control processor 110.

The laser control processor 30 controls the rotation stage 412 of the first prism 41 based on both the first target wavelength Dλ1t and the second target wavelength Dλ2t received from the exposure control processor 110 or the difference between these target wavelengths. By changing the posture of the first prism 41 by the rotation stage 412, the state of the light beam is switched between a first state in which the light beam having passed through the first prism 41 is incident on the grating 53 at the first incident angle and a second state in which the light beam having passed through the first prism 41 is incident on the grating 53 at the second incident angle. FIG. 13A shows the optical paths of the light beams in two types being in the first state and the second state. The laser control processor 30 controls the rotation stage 412 so that the posture of the first prism 41 is switched every predetermined number of pulses of the pulse laser light. Thus, the wavelength of the pulse laser light is switched between a value near the first target wavelength Dλ1t and a value near the second target wavelength Dλ2t every predetermined number of pulses.

In the single-wavelength mode shown in FIGS. 13C and 13D, the laser control processor 30 controls the rotation stage 422 of the second prism 42 based on the first target wavelength Dλ1t received from the exposure control processor 110. The laser control processor 30 may leave the light beam in the first state without changing the posture of the first prism 41 in the single-wavelength mode.

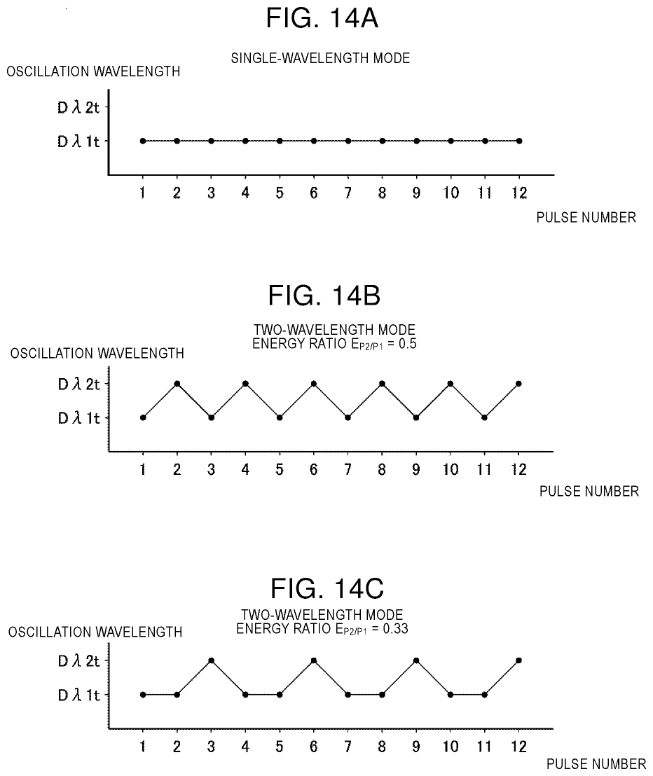

FIGS. 14A to 14C are graphs showing changes of the oscillation wavelength in the second embodiment. In the figures, the horizontal axis represents the pulse number and the vertical axis represents the oscillation wavelength.

FIG. 14A shows the oscillation wavelength when laser oscillation is performed in the single-wavelength mode. In the single-wavelength mode, the oscillation wavelength is substantially fixed near the first target wavelength Dλ1t.

FIG. 14B shows an exemplary change of the oscillation wavelength when laser oscillation is performed in the two-wavelength mode. In the example shown in FIG. 14B, a pulse near the first target wavelength Dλ1t and a pulse near the second target wavelength Dλ2t are alternately output one pulse at a time.

FIG. 14C shows another example of the change of the oscillation wavelength when laser oscillation is performed in the two-wavelength mode. In the example shown in FIG. 14C, two pulses near the first target wavelength Dλ1t and one pulse near the second target wavelength Dλ2 are alternately output.

As an example of the energy ratio parameter in the second embodiment, the energy ratio E_{P2/P1} is defined by the following equation.

E_{P2/P1}=P2/(P1+P2)

Here, P1 is the number of pulses of the first target wavelength Dλ1t per wavelength change cycle, and P2 is the number of pulses of the second target wavelength Dλ2t per wavelength change cycle. It is assumed that the pulse energy of the first target wavelength Dλ1t and the pulse energy of the second target wavelength Dλ2t are the same.

The energy ratio E_{P2/P1} in FIG. 14B is 0.5.

The energy ratio E_{P2/P1} in FIG. 14C is 0.33.

The laser control processor 30 receives the target value E_{P2/P1}t of the energy ratio E_{P2/P1} from the exposure control processor 110. Based on the target value E_{P2/P1}t, the laser control processor 30 determines the number of pulses P1 of the first target wavelength Dλ1t per wavelength change cycle and the number of pulses P2 of the second target wavelength Dλ2t per wavelength change cycle. The laser control processor 30 sets the control timing of the rotation stage 412 based on P1 and P2.

The operation of the exposure control processor 110 in the second embodiment is the same as that described with reference to FIG. 5.

### 3.3 Operation of Single-Wavelength Mode by Laser Control Processor 30

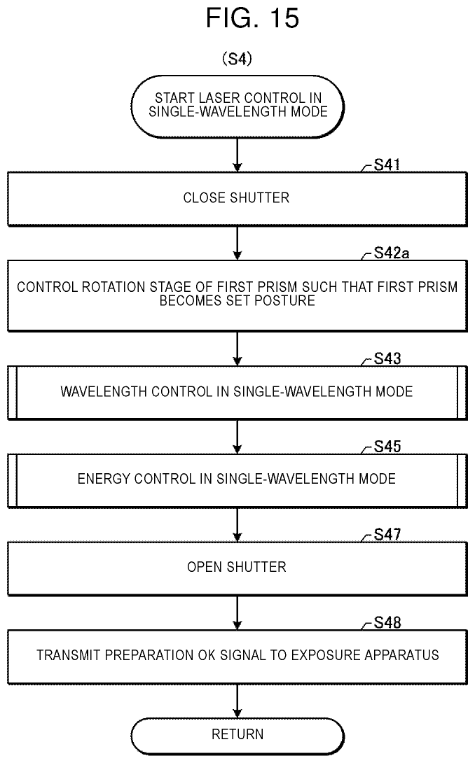

FIG. 15 is a flowchart showing a processing procedure of the single-wavelength mode in the second embodiment. When the laser control processor 30 receives the single-wavelength mode command and various target values from the exposure control processor 110 according to the processing of FIG. 5, the laser control processor 30 performs laser control in the single-wavelength mode by the following processing.

In S41, the laser control processor 30 closes the shutter 18. This is similar to the corresponding process in FIG. 6.

Next, in S42a, the laser control processor 30 controls the rotation stage 412 so that the posture of the first prism 41 becomes a preset posture. In the single-wavelength mode, it is not necessary to adjust the first prism. 41 in accordance with the target value and the measurement value. The control in accordance with the target value and the measurement value is performed on the second prism 42.

The subsequent processes of S43 to S48 are similar to the corresponding processes in FIG. 6.

The subroutine of the wavelength control in the single-wavelength mode (S43) is similar to that described with reference to FIG. 7. The subroutine of the energy control in the single-wavelength mode (S45) is similar to that described with reference to FIG. 8.

### 3.4 Operation of Two-Wavelength Mode by Laser Control Processor 30

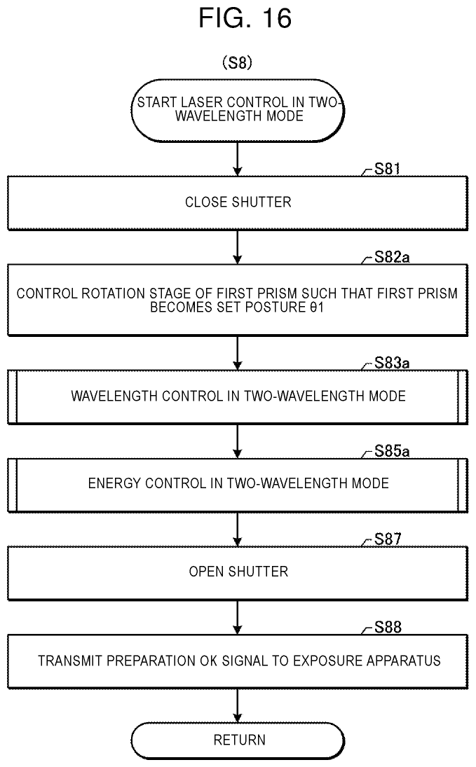

FIG. 16 is a flowchart showing a processing procedure of the two-wavelength mode in the second embodiment. When the laser control processor 30 receives the two-wavelength mode command and various target values from the exposure control processor 110, the laser control processor 30 performs laser control in the two-wavelength mode by the following processing.

In S81, the laser control processor 30 closes the shutter 18. This is similar to the corresponding process in FIG. 9.

Next, in S82a, the laser control processor 30 controls the rotation stage 412 so that the posture of the first prism 41 becomes a preset posture θ1. In the two-wavelength mode, the posture of the first prism 41 is controlled by being switched between the posture θ1 and the posture θ2 determined later. The posture θ1 is a posture of the first prism 41 for laser oscillation at the first target wavelength Dλ1t, and the posture θ2 is a posture of the first prism 41 for laser oscillation at the second target wavelength Dλ2t. For example, when it is known in advance that θ2 is larger than θ1 from the magnitude relationship between the first target wavelength Dλ1t and the second target wavelength Dλ2t, the minimum value in the movable range of the rotation stage 412 may be set as θ1.

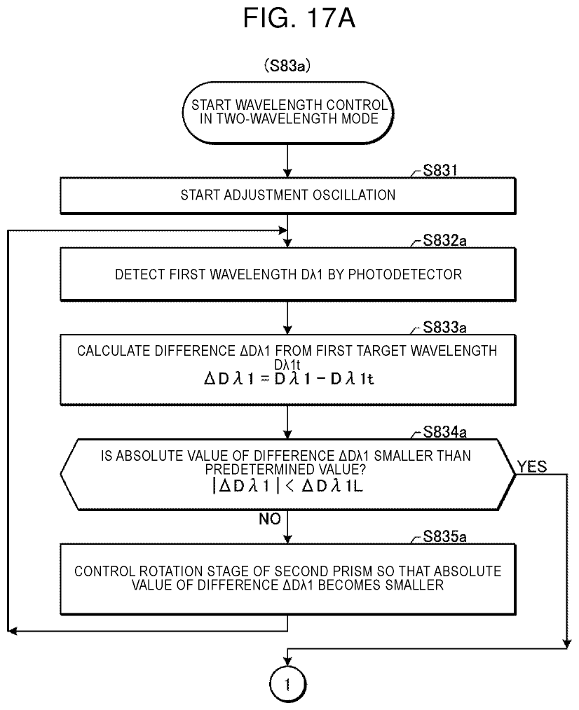

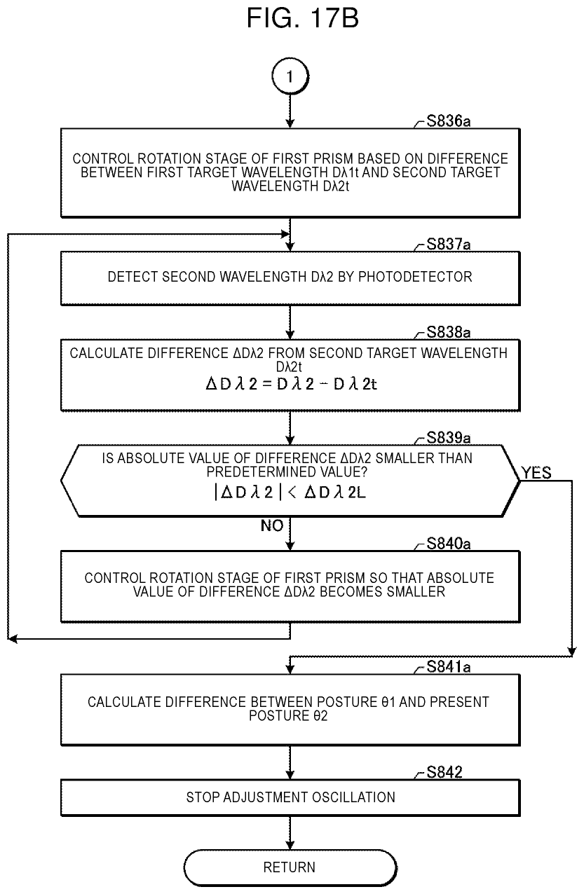

Next, in S83a, the laser control processor 30 performs the wavelength control in the two-wavelength mode. The wavelength control in the two-wavelength mode will be described later with reference to FIGS. 17A and 17B.

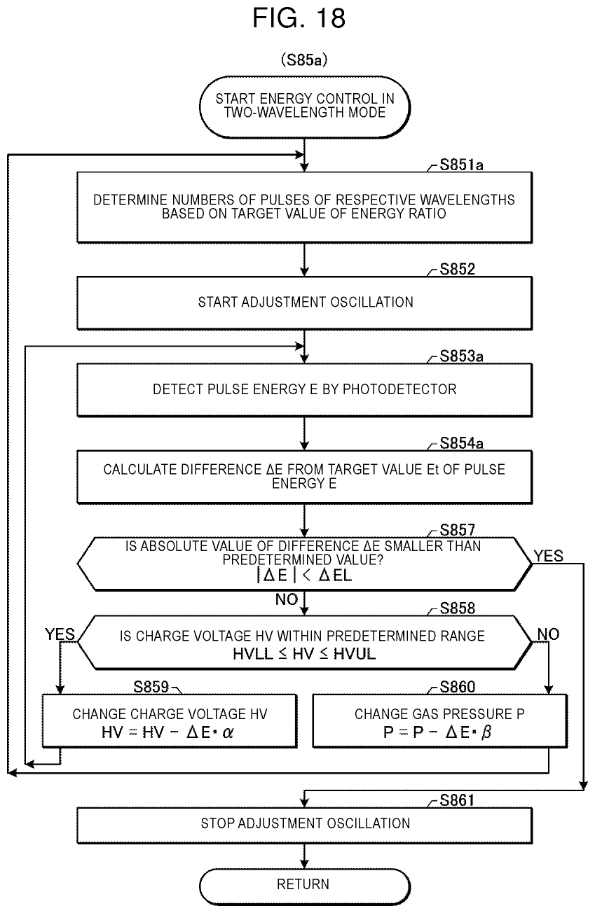

Next, in S85a, the laser control processor 30 performs the energy control in the two-wavelength mode. The energy control in the two-wavelength mode will be described later with reference to FIG. 18.

The next processes of S87 and S88 are similar to the corresponding processes in FIG. 9.

### 3.4.1 Wavelength Control in Two-Wavelength Mode

FIGS. 17A and 17B are flowcharts showing processing procedures of the wavelength control in the two-wavelength mode. The processing shown in FIGS. 17A and 17B corresponds to the subroutine of S83a in FIG. 16.

In S831, the laser control processor 30 starts adjustment oscillation to set the wavelength. This is similar to the corresponding process in FIG. 10.

### 3.4.1.1 Process for Determining Posture of Second Prism 42

Next, in S832a, the laser control processor 30 detects the wavelength Dλ1 of the pulse laser light by the photodetector 17.

Next, in S833a, the laser control processor 30 calculates the difference ΔDλ1 between the detected wavelength Dλ1 and the first target wavelength Dλ1t by the following equation.

ΔDλ1=Dλ1−Dλ1t

The first target wavelength Dλ1t is one of the target wavelengths received from the exposure control processor 110.

Next, in S834a, the laser control processor 30 determines whether or not the absolute value |ΔDλ1| of the difference ΔDλ1 is smaller than a predetermined value ΔDλ1L. When the absolute value |ΔDλ1| of the difference ΔDλ1 is equal to or larger than the predetermined value ΔDλ1L (NO in S834a), the laser control processor 30 advances processing to S835a. When the absolute value |ΔDλ1| of the difference ΔDλ1 is smaller than the predetermined value ΔDλ1L (YES in S834a), the laser control processor 30 advances processing to S836a.

In S835a, the laser control processor 30 controls the rotation stage 422 of the second prism 42 so that the absolute value |ΔDλ1| of the difference ΔDλ1 becomes smaller, that is, so that the wavelength Dλ1 approaches the first target wavelength Dλ1t. After S835a, the laser control processor 30 returns processing to S832a. By repeating the processes of S832a to S835a, the posture of the second prism 42 for obtaining the first target wavelength Dλ1t is determined. The posture of the second prism 42 is also maintained in the processing of FIG. 17B. The laser control processor 30 stores the posture of the second prism 42 in the memory 32.

### 3.4.1.2 Process for Determining Amplitude of First Prism 41

Referring to FIG. 17B, in S836a, the laser control processor 30 controls the rotation stage 412 for the first prism 41 based on the difference between the first target wavelength Dλ1t and the second target wavelength Dλ2t. The second target wavelength Dλ2t is one of the target wavelengths received from the exposure control processor 110.

Next, in S837a, the laser control processor 30 detects the wavelength Dλ2 of the pulse laser light by the photodetector 17.

Next, in S838a, the laser control processor 30 calculates the difference ΔDλ2 between the detected wavelength Dλ2 and the second target wavelength Dλ2t by the following equation.

ΔDλ2=Dλ2−Dλ2t

Next, in S839a, the laser control processor 30 determines whether or not the absolute value |ΔDλ2| of the difference ΔDλ2 is smaller than a predetermined value ΔDλ2L. When the absolute value |ΔDλ2| of the difference ΔDλ2 is equal to or larger than the predetermined value ΔDλ2L (NO in S839a), the laser control processor 30 advances processing to S840a. When the absolute value |ΔDλ2| of the difference ΔDλ2 is smaller than the predetermined value ΔDλ2L (YES in S839a), the laser control processor 30 advances processing to S841a.

In S840a, the laser control processor 30 controls the rotation stage 412 of the first prism 41 so that the absolute value |ΔDλ2| of the difference ΔDλ2 becomes smaller, that is, so that the wavelength Dλ2 approaches the second target wavelengths Dλ2t. After S840a, the laser control processor 30 returns processing to S837a.

In S841a, the laser control processor 30 calculates the difference between the posture θ1 and the present posture θ2 of the first prism 41. The laser control processor 30 stores the calculated posture difference in the memory 32. The difference between θ1 and θ2 corresponds to the wavelength amplitude for switching from the first target wavelength Dλ1t to the second target wavelength Dλ2t by the first prism 41. The wavelength amplitude is determined by the processes of S836a to S841a.

Next, in S842, the laser control processor 30 stops the adjustment oscillation. After S842, the laser control processor 30 ends the processing of the present flowchart and returns to the processing shown in FIG. 16.

### 3.4.2 Energy Control in Two-Wavelength Mode

FIG. 18 is a flowchart showing a processing procedure of the energy control in the two-wavelength mode. The processing shown in FIG. 18 corresponds to the subroutine of S85a in FIG. 16.

In S851a, the laser control processor 30 determines the numbers of pulses P1, P2 of the respective wavelengths per wavelength change cycle based on the target value E_{P2/P1}t of the energy ratio E_{P1/P2}.

Next, in S852, the laser control processor 30 starts the adjustment oscillation to set the pulse energy. In this adjustment oscillation, laser oscillation is performed while switching the wavelength in accordance with the posture of the second prism 42 and the amplitude of the first prism 41 determined in the processing of FIGS. 17A and 17B and the numbers of pulses P1, P2 of the respective wavelengths per wavelength change cycle determined in the process of S851.

Next, in S853a, the laser control processor 30 detects the pulse energy E by the photodetector 17. It is assumed that the pulse energy E of the pulse laser light output at the first target wavelength Dλ1t and the pulse energy E of the pulse laser light output at the second target wavelength Dλ2t are the same.

Next, in S854a, the laser control processor 30 calculates the difference ΔE between the detected pulse energy E and the target value Et of the pulse energy E by the following equation.

ΔE=E−Et

The following processes of S857 to S861 are the same as those described with reference to FIG. 11.

### 3.5 Other Configuration Example

In the second embodiment, description has been provided on a case in which the exposure control processor 110 included in the exposure apparatus 100 outputs the single-wavelength mode command, the two-wavelength mode command, data of other target values, and the like, but the present disclosure is not limited thereto. For example, a controller of an external apparatus (not shown) that controls a plurality of exposure apparatuses 100 may output these commands and data.

In the second embodiment, description has been provided on the line narrowing gas laser device 1 capable of setting the first and second target wavelengths Dλ1t, Dλ2t and outputting while switching between the two wavelengths, but the present disclosure is not limited thereto. For example, three or more target wavelengths may be set, so that laser oscillation at three or more wavelengths can be performed.

### 3.6 Effect

In the second embodiment, the line narrowing gas laser device 1 includes the line narrowing device 14b. The line narrowing device 14b includes the grating 53, the first prism 41, and the rotation stage 412. The rotation stage 412 corresponds to the first actuator in the present disclosure. The first prism 41 is arranged on the optical path of the light beam and causes the light beam to be incident on the grating 53. The rotation stage 412 switches the state of the light beam between the first state in which the light beam having passed through the first prism 41 is incident on the grating 53 at the first incident angle and the second state in which the light beam having passed through the first prism 41 is incident on the grating 53 at the second incident angle. The laser control processor 30 controls the rotation stage 412 so that the state of the light beam becomes the first state when receiving the single-wavelength mode command from the external apparatus, and controls the rotation stage 412 so that the state of the light beam is switched between the first state and the second state every predetermined number of pulses of the pulse laser light when receiving the multi-wavelength mode command from the external apparatus. According to the above, the single-wavelength mode and the multi-wavelength mode can be performed without providing the plane-parallel substrate 61 (FIGS. 4A to 4D).

In the second embodiment, the laser control processor 30 reads the first target wavelength Dλ1t of the pulse laser light output in the first state and the second target wavelength Dλ2t of the pulse laser light output in the second state when receiving the multi-wavelength mode command from the external apparatus. The laser control processor 30 performs the adjustment oscillation based on the first and second target wavelengths Dλ1t, Dλ2t to determine a control value of the rotation stage 412 for switching the state of the light beam between the first state and the second state. According to the above, it is possible to perform control with high accuracy so as to realize target values of the plurality of wavelengths.

In the second embodiment, the line narrowing device 14b further includes the second prism 42 arranged on the optical path of the light beam between the first prism 41 and the grating 53, and the rotation stage 422 which adjusts the posture of the second prism 42. The rotation stage 422 corresponds to the second actuator in the present disclosure. In the adjustment oscillation, the posture of the second prism 42 is adjusted so that the wavelength of the pulse laser light output in the state in which the first prism 41 is set to the first posture becomes near the first target wavelength Dλ1t, and the adjusted posture of the second prism 42 is stored as the second posture. According to the above, it is possible to perform control with high accuracy so as to realize target values of the plurality of wavelengths.

In the second embodiment, the laser control processor 30 adjusts the posture of the first prism 41 so that the wavelength of the pulse laser light output in the state in which the second prism 42 is set to the second posture becomes near the second target wavelength Dλ2t, and stores the difference between the adjusted posture of the first prism 41 and the first posture. It is possible to control the first prism 41 using the difference as the amplitude of the first prism 41 for each predetermined number of pulses. Since the first prism 41 is arranged at a position before the second prism 42, that is, before the beam width is expanded, high-speed control can be performed with the small-sized first prism 41.

The present embodiment exemplifies the case in which the rotation stage 422 for the second prism 42 is controlled based on the first target wavelength Dλ1t, but the present disclosure is not limited thereto. When the wavelengths Dλ1, Dλ2 can be adjusted to the first target wavelength Dλ1t and the second target wavelength Dλ2t, respectively, only by controlling the rotation of the first prism 41, the rotation of the second prism 42 may not be controlled.

In the second embodiment, the laser control processor 30 reads the target value E_{λ2/λ1}t of the energy ratio as the target value of the energy ratio parameter between the pulse laser light output in the first state and the pulse laser light output in the second state when receiving the multi-wavelength mode command from the external apparatus. Based on the target value E_{λ2/λ1}t of the energy ratio, the laser control processor 30 determines the ratio of the first number of pulses P1 of the pulse laser light output in the first state and the second number of pulses P2 of the pulse laser light output in the second state. According to the above, the energy ratio can be controlled by simple calculation.

### 4. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A control method of a line narrowing gas laser device, comprising:
receiving a command of either a single-wavelength mode command or a multi-wavelength mode command from an external apparatus; and
controlling the line narrowing gas laser device to generate pulse laser light in accordance with the command.

2. The control method according to claim 1,
wherein the line narrowing gas laser device includes a line narrowing device,
the line narrowing device includes:
a grating system;
a beam adjustment optical system which is arranged on an optical path of a light beam and configured to adjust the optical path of at least apart of the light beam so as to cause a first portion of the light beam to be incident on a first region of the grating system and a second portion of the light beam to be incident on a second region of the grating system; and
an adjustment mechanism configured to adjust an energy ratio of a wavelength component of a second wavelength selected as being incident on the second region to a wavelength component of a first wavelength selected as being incident on the first region by adjusting either a position or posture of at least one optical element included in the beam adjustment optical system, and
the controlling the line narrowing gas laser device includes controlling the adjustment mechanism so that the energy ratio of the wavelength component of the second wavelength becomes a minimum value when the single-wavelength mode command is received from the external apparatus, and controlling the adjustment mechanism so that the energy ratio of the wavelength component of the second wavelength becomes larger than the minimum value when the multi-wavelength mode command is received from the external apparatus.

3. The control method according to claim 2,
wherein the adjustment mechanism adjusts the beam adjustment optical system so that the entire light beam is incident on the first region when the single-wavelength mode command is received from the external apparatus.

4. The control method according to claim 2,
wherein the line narrowing device further includes a first actuator configured to adjust an incident angle of the first portion on the grating system, and a second actuator configured to adjust an incident angle of the second portion on the grating system, and
the controlling the line narrowing gas laser device includes:
reading a target value of a first wavelength parameter related to the first wavelength and a target value of a second wavelength parameter related to the second wavelength when the multi-wavelength mode command is received from the external apparatus; and
controlling the first and second actuators based on the target values of the first and second wavelength parameters as performing adjustment oscillation.

5. The control method according to claim 4,
wherein the first wavelength parameter includes the first wavelength, and
the second wavelength parameter includes the second wavelength.

6. The control method according to claim 4,
wherein the first wavelength parameter includes the first wavelength, and
the second wavelength parameter includes a wavelength difference between the first wavelength and the second wavelength.

7. The control method according to claim 4,
wherein the controlling the line narrowing gas laser device includes:
reading a target value of an energy ratio parameter between the wavelength component of the first wavelength and the wavelength component of the second wavelength when the multi-wavelength mode command is received from the external apparatus; and
controlling the adjustment mechanism based on the target value of the energy ratio parameter after controlling the first and second actuators based on the target values of the first and second wavelength parameters.

8. The control method according to claim 7,
wherein the energy ratio parameter includes a combination of energy of the wavelength component of the first wavelength and energy of the wavelength component of the second wavelength.

9. The control method according to claim 7,
wherein the energy ratio parameter includes a value obtained by dividing energy of the wavelength component of the second wavelength by energy of the wavelength component of the first wavelength.

10. The control method according to claim 7,
wherein the energy ratio parameter includes:
a value obtained by dividing energy of the wavelength component of the first wavelength by a total value in which the energy of the wavelength component of the first wavelength and energy of the wavelength component of the second wavelength are added; and
a value obtained by dividing the energy of the wavelength component of the second wavelength by the total value.

11. The control method according to claim 7,
wherein the line narrowing gas laser device further includes a laser chamber in which a pair of electrodes are arranged and laser gas is accommodated, and a charger configured to apply a voltage between the electrodes, and
the controlling the line narrowing gas laser device includes:
reading a target value of total pulse energy of the wavelength component of the first wavelength and the wavelength component of the second wavelength when the multi-wavelength mode command is received from the external apparatus; and
controlling charge voltage of the charger and gas pressure in the laser chamber based on the target value of the total pulse energy after the adjustment mechanism is controlled based on the target value of the energy ratio parameter.

12. The control method according to claim 1,
wherein the line narrowing gas laser device includes a line narrowing device,
the line narrowing device includes:
a grating;
a first prism arranged on the optical path of the light beam and configured to cause the light beam to be incident on the grating; and
a first actuator configured to switch a state of the light beam between a first state in which the light beam having passed through the first prism is incident on the grating at a first incident angle and a second state in which the light beam having passed through the first prism is incident on the grating at a second incident angle, and
the controlling the line narrowing gas laser device includes:
controlling the first actuator so that the state of the light beam becomes the first state when the single-wavelength mode command is received from the external apparatus, and
controlling the first actuator so that the state of the light beam is switched between the first state and the second state every predetermined number of pulses of the pulse laser light when the multi-wavelength mode command is received from the external apparatus.

13. The control method according to claim 12,
wherein the controlling the line narrowing gas laser device includes:
reading a first target wavelength of the pulse laser light to be output in the first state and a second wavelength of the pulse laser light to be output in the second state when the multi-wavelength mode command is received from the external apparatus; and
determining a control value of the first actuator for switching the state of the light beam between the first state and the second state as performing adjustment oscillation based on the first and second target wavelengths.

14. The control method according to claim 13,
wherein the line narrowing device further includes a second prism arranged on the optical path of the light beam between the first prism and the grating, and a second actuator configured to adjust posture of the second prism, and
the adjustment oscillation includes adjusting the posture of the second prism so that a wavelength of pulse laser light to be output in a state in which the first prism is set to first posture becomes near the first target wavelength and storing the adjusted posture of the second prism as second posture.

15. The control method according to claim 14,
wherein the adjustment oscillation further includes adjusting posture of the first prism so that a wavelength of pulse laser light output in a state in which the second prism is set to the second posture becomes near the second target wavelength and storing a difference between the adjusted posture of the first prism and the first posture.

16. The control method according to claim 12,
wherein the controlling the line narrowing gas laser device includes:
reading a target value of the energy ratio of the pulse laser light to be output in the first state and the pulse laser light to be output in the second state when the multi-wavelength mode command is received from the external apparatus; and
determining a ratio of a first number of pulses of the pulse laser light to be output in the first state and a second number of pulses of the pulse laser light to be output in the second state based on the target value of the energy ratio.

17. A line narrowing gas laser device, comprising:
a laser chamber;
an optical resonator including a line narrowing device; and
a processor,
the processor being configured to receive, from an external apparatus, a command being either a single-wavelength mode command or a multi-wavelength mode command and to control the line narrowing gas laser device to generate pulse laser light in accordance with the command.

18. The line narrowing gas laser device according to claim 17,
wherein the line narrowing device includes:
a grating system,
a beam adjustment optical system arranged on an optical path of a light beam and configured to adjust the optical path of at least a part of the light beam so as to cause a first portion of the light beam to be incident on a first region of the grating system and a second portion of the light beam to be incident on a second region of the grating system; and
an adjustment mechanism configured to adjust an energy ratio of a wavelength component of a second wavelength selected as being incident on the second region to a wavelength component of a first wavelength selected as being incident on the first region by adjusting either a position or posture of at least one optical element included in the beam adjustment optical system, and
the processor controls the adjustment mechanism so that the energy ratio of the wavelength component of the second wavelength becomes a minimum value when the single-wavelength mode command is received from the external apparatus and controls the adjustment mechanism so that the energy ratio of the wavelength component of the second wavelength becomes larger than the minimum value when the multi-wavelength mode command is received from the external apparatus.

19. The line narrowing gas laser device according to claim 17,
wherein the line narrowing device includes:
a grating;
a first prism arranged on an optical path of a light beam and configured to cause the light beam to be incident on the grating; and
a first actuator configured to switch a state of the light beam between a first state in which the light beam having passed through the first prism is incident on the grating at a first incident angle and a second state in which the light beam having passed through the first prism is incident on the grating at a second incident angle, and
the processor controls the first actuator so that the state of the light beam becomes the first state when the single-wavelength mode command is received from the external apparatus, and controls the first actuator so that the state of the light beam is switched between the first state and the second state every predetermined number of pulses of the pulse laser light when the multi-wavelength mode command is received from the external apparatus.

20. An electronic device manufacturing method, comprising:
generating pulse laser light using a line narrowing gas laser device;
outputting the pulse laser light to an exposure apparatus; and
exposing a photosensitive substrate to the pulse laser light in the exposure apparatus to manufacture an electronic device,
the line narrowing gas laser device including:
a laser chamber;
an optical resonator including a line narrowing device; and
a processor, and
the processor being configured to receive, from an external apparatus, a command being either a single-wavelength mode command or a multi-wavelength mode command and to control the line narrowing gas laser device to generate the pulse laser light in accordance with the command.
